(19) United States
(12) Patent Application Publication
(10) Pub. No.: US 2026/0040666 A1
(43) Pub. Date: Feb. 5, 2026

(54) SEMICONDUCTOR DEVICE

(71) Applicant: Samsung Electronics Co., Ltd., Suwon-si (KR)

(72) Inventors: Seongkwang KIM, Suwon-si (KR); Donghoon HWANG, Suwon-si (KR); Minwoo KIM, Suwon-si (KR); Byungho MOON, Suwon-si (KR); Wonchang LEE, Suwon-si (KR); Jaeho JEON, Suwon-si (KR); Jina KIM, Suwon-si (KR); Hyunsoo KIM, Suwon-si (KR)

(73) Assignee: Samsung Electronics Co., Ltd., Suwon-si (KR)

(21) Appl. No.: 19/064,825

(22) Filed: Feb. 27, 2025

(30) Foreign Application Priority Data
Aug. 1, 2024 (KR) 10-2024-0102670

(51) Int. Cl. H10D 84/83; H10D 30/00; H10D 30/01; H10D 62/10; H10D 64/23; H10D 64/27; H10D 84/01

(52) U.S. Cl. CPC H10D 84/832; H10D 30/502; H10D 62/121; H10D 64/254; H10D 64/518; H10D 84/8312; H10D 84/83125; H10D 30/0191; H10D 84/0149

(57) ABSTRACT

Provided is a semiconductor device including a lower source/drain pattern, a lower channel structure connected to the lower source/drain pattern, a lower gate electrode overlapping the lower channel structure and extending in a first direction, a lower active contact on the lower source/drain pattern, an upper channel structure overlapping the lower channel structure, an upper source/drain pattern connected to the upper channel structure, an upper gate electrode overlapping the upper channel structure and extending in the first direction, an interlayer structure between the lower channel structure and the upper channel structure, and a through active contact extending through the interlayer structure, and electrically connected to the upper source/drain pattern and the lower active contact.

### CROSS-REFERENCE TO RELATED APPLICATIONS

This U.S. non-provisional patent application claims priority under 35 U.S.C. § 119 of Korean Patent Application No. 10-2024-0102670, filed on Aug. 1, 2024, the entire contents of which are hereby incorporated by reference.

### BACKGROUND

The present disclosure herein relates to semiconductor devices, and more particularly, to semiconductor devices including a through active contact.

A semiconductor device includes an integrated circuit composed of metal-oxide-semiconductor field effect transistors (MOSFET). As a size and a design rule of the semiconductor device are gradually decreasing, scaling down of the metal-oxide-semiconductor field effect transistors is also gradually being accelerated. As the metal-oxide-semiconductor field effect transistors are gradually scaled down, operation characteristics of the semiconductor device may be deteriorated. Accordingly, research on various methods for overcoming limitation caused by higher-integration of the semiconductor device and/or forming the semiconductor device with improved performance is being conducted.

### SUMMARY

Some example embodiments of the present disclosure provide semiconductor devices with improved electrical characteristics and/or reliability.

In an example embodiment of the inventive concepts, a semiconductor device includes a lower source/drain pattern, a lower channel structure connected to the lower source/drain pattern, a lower gate electrode overlapping the lower channel structure, the lower gate electrode extending in a first direction, a lower active contact on the lower source/drain pattern, an upper channel structure overlapping the lower channel structure, an upper source/drain pattern connected to the upper channel structure, an upper gate electrode overlapping the upper channel structure, the upper gate electrode extending in the first direction, an interlayer structure between the lower channel structure and the upper channel structure, and a through active contact extending through the interlayer structure, the through active contact electrically connected to the upper source/drain pattern and the lower active contact, wherein the lower active contact includes an active conductive portion and an active via portion, the active conductive portion being on the lower source/drain pattern, the active via portion being on the active conductive portion, and a width in the first direction of the active conductive portion is greater than a width in the first direction of the active via portion.

In an example embodiment of the inventive concepts, a semiconductor device includes a lower source/drain pattern, a lower channel structure connected to the lower source/drain pattern, a lower gate electrode overlapping the lower channel structure, the lower gate electrode extending in a first direction, a lower active contact on the lower source/drain pattern, an upper channel structure overlapping the lower channel structure, an upper source/drain pattern connected to the upper channel structure, an upper gate electrode overlapping the upper channel structure, the upper gate electrode extending in the first direction, an interlayer structure between the lower channel structure and the upper channel structure, a mask layer between the interlayer structure and the lower active contact, and a through active contact extending through the interlayer structure, the through active contact electrically connected to the upper source/drain pattern and the lower active contact, wherein the lower active contact includes an active conductive portion and an active via portion, the active conductive portion being on the lower source/drain pattern, the active via portion being on the active conductive portion, and the mask layer is in contact with an upper surface of the active conductive portion and a sidewall of the active via portion.

In an example embodiment of the inventive concepts, a semiconductor device includes a lower source/drain pattern, a lower channel structure connected to the lower source/drain pattern, a lower gate electrode overlapping the lower channel structure, the lower gate electrode extending in a first direction, a lower active contact on the lower source/drain pattern, an upper channel structure overlapping the lower channel structure, an upper source/drain pattern connected to the upper channel structure, an upper gate electrode overlapping the upper channel structure, the upper gate electrode extending in the first direction, an interlayer structure between the lower channel structure and the upper channel structure, a mask layer between the interlayer structure and the lower active contact, a through active contact extending through the interlayer structure and the mask layer, the through active contact electrically connected to the upper source/drain pattern and the lower active contact, and a gate connection contact electrically connected to the lower gate electrode and the upper gate electrode, wherein the lower active contact includes an active conductive portion and an active via portion, the active conductive portion being on the lower source/drain pattern, the active via portion being on the active conductive portion, the lower gate electrode includes a gate conductive portion and a gate via portion, the gate conductive portion overlapping the lower channel structure, the gate via portion on the gate conductive portion, and the active via portion and the gate via portion are at higher levels than a lower surface of the mask layer.

### BRIEF DESCRIPTION OF THE FIGURES

The accompanying drawings are included to provide a further understanding of the inventive concepts, and are incorporated in and constitute a part of this specification. The drawings illustrate some example embodiments of the inventive concepts and serve to explain principles of the inventive concepts. In the drawings:

FIG. 1A is a plan view of a semiconductor device according to an example embodiment;

FIG. 1B is a cross-sectional view taken along line A-A′ of FIG. 1A;

FIG. 1C is a cross-sectional view taken along line B-B′ of FIG. 1A;

FIG. 1D is a cross-sectional view taken along line C-C′ of FIG. 1A;

FIG. 1E is an enlarged view of region ‘E1’ of FIG. 1A;

FIG. 1F is an enlarged view of region ‘E2’ of FIG. 1B;

FIG. 1G is an enlarged view of region ‘E3’ of FIG. 1C;

FIG. 1H is an enlarged view of region ‘E4’ of FIG. 1D;

FIGS. 2A, 2B, 3A, 3B, 3C, 4A, 4B, 4C, 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 14A, 14B, 15A, 15B, and 15C are diagrams for describing a method for manufacturing a semiconductor device according to FIGS. 1A to 1H;

FIG. 16 is a plan view of a semiconductor device according to an example embodiment;

FIG. 17 is an enlarged cross-sectional view of a semiconductor device according to an example embodiment; and

FIG. 18 is an enlarged cross-sectional view of a semiconductor device according to an example embodiment.

### DETAILED DESCRIPTION

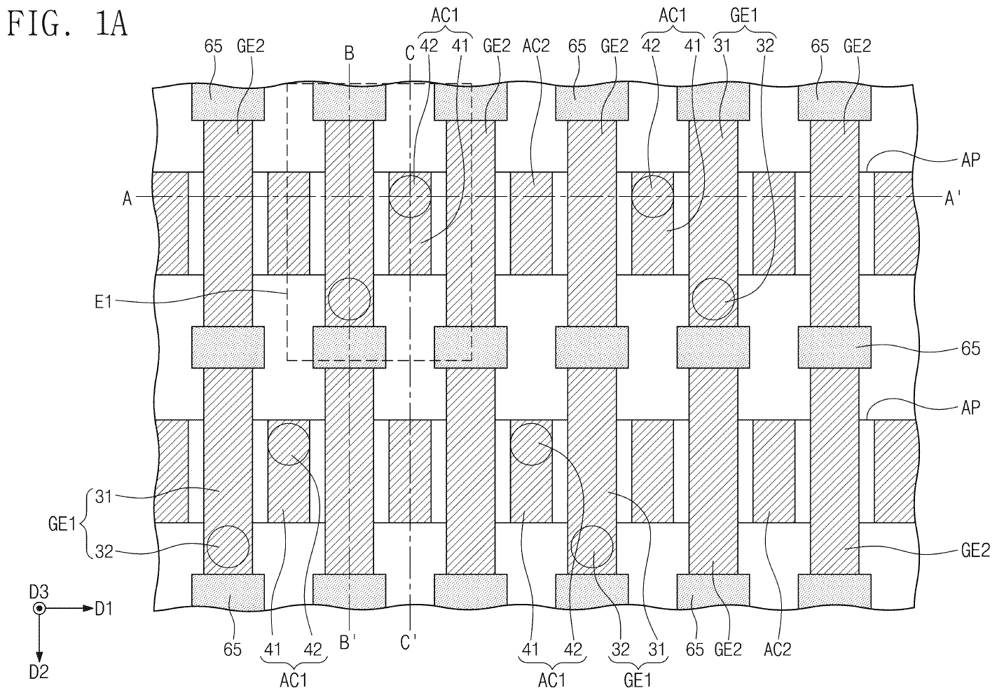

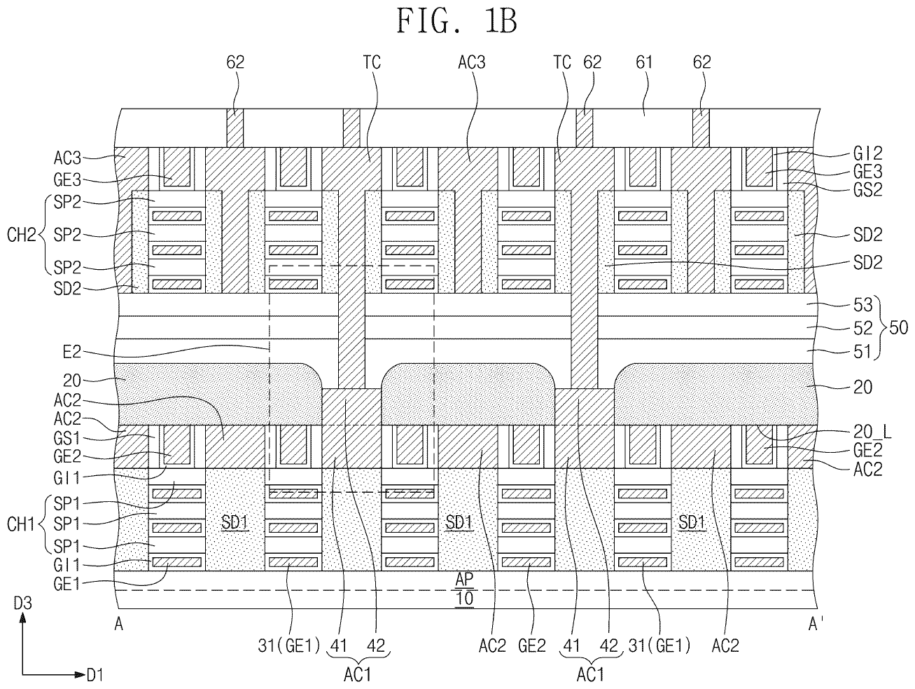

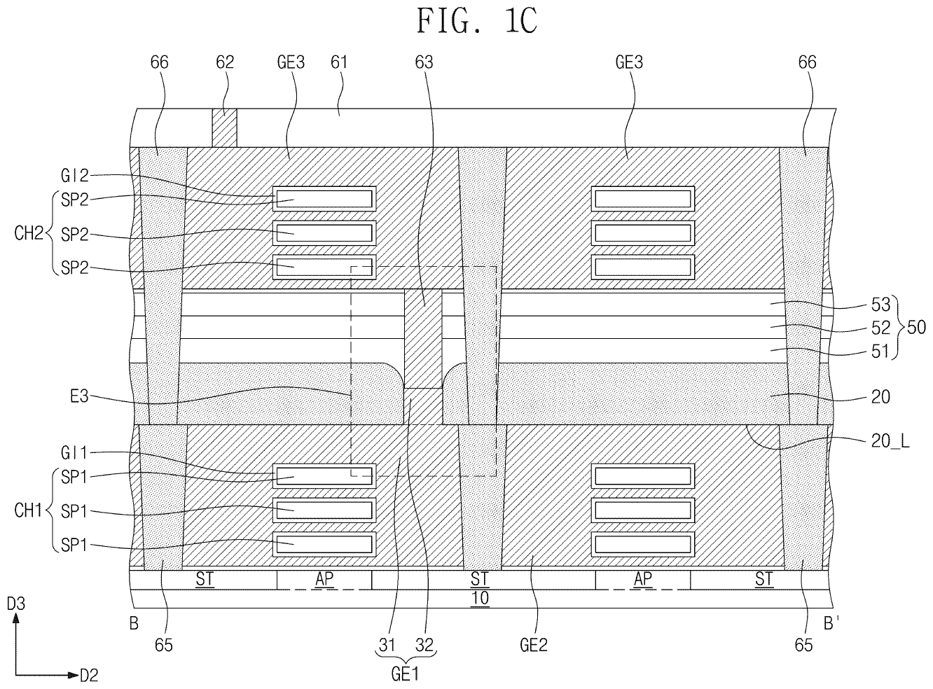

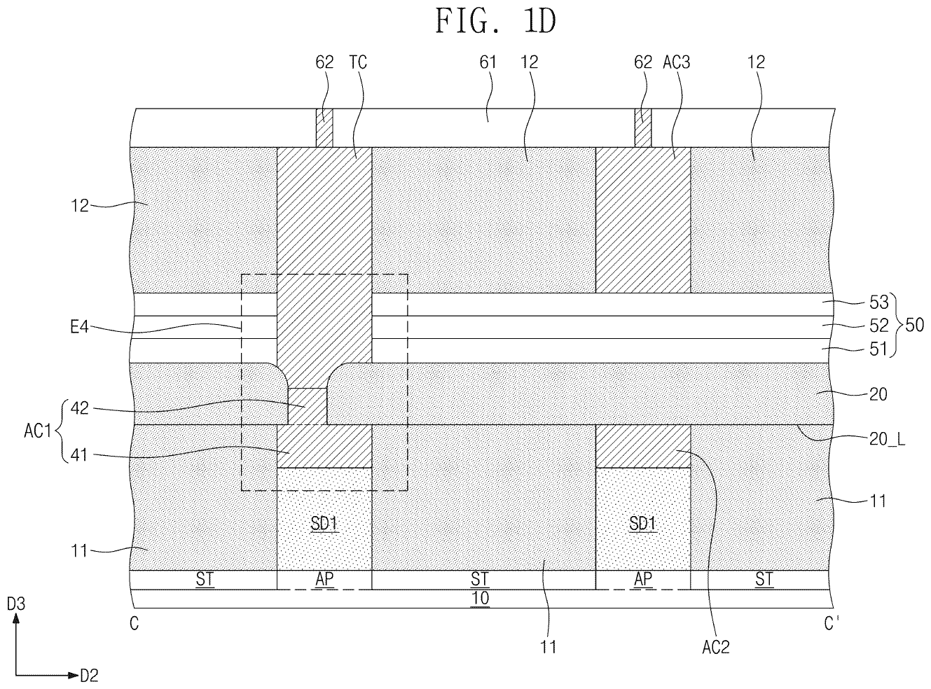

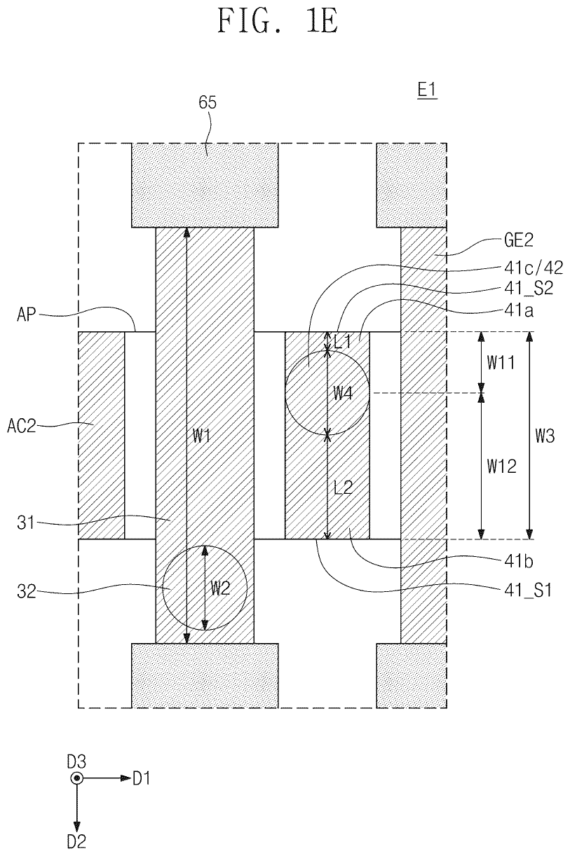

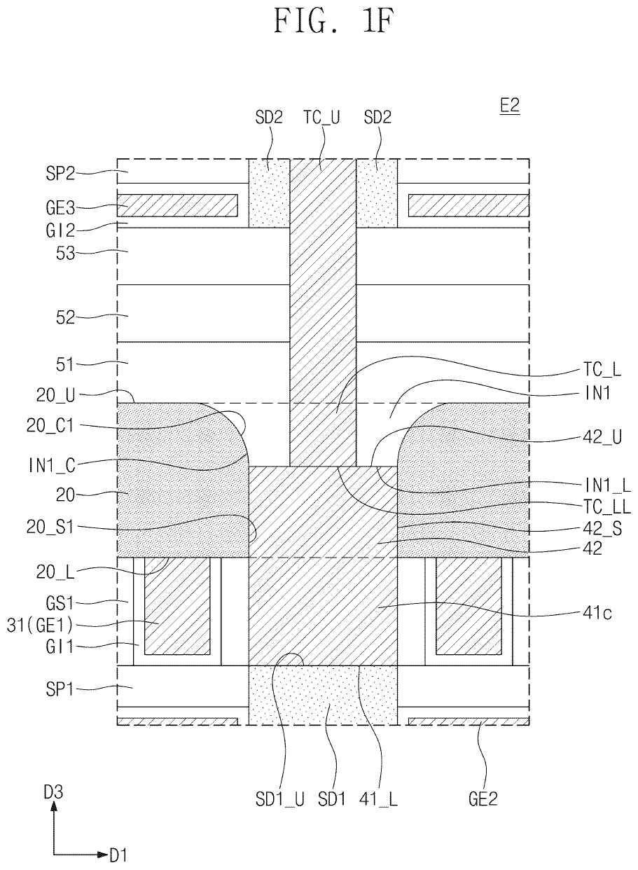

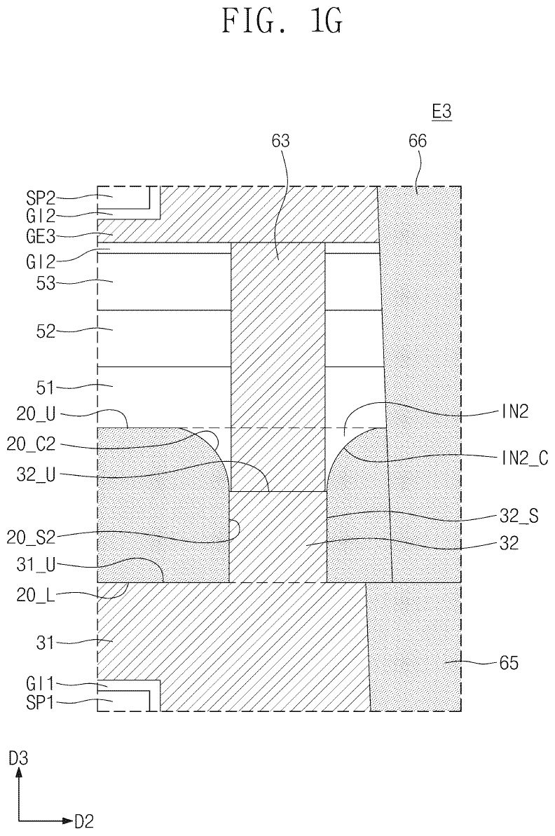

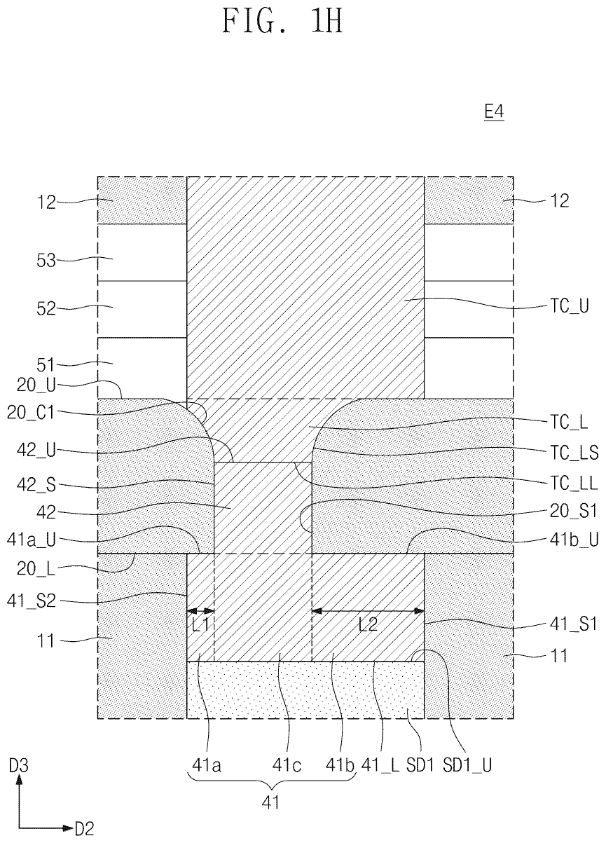

FIG. 1A is a plan view of a semiconductor device according to an example embodiment. FIG. 1B is a cross-sectional view taken along line A-A′ of FIG. 1A. FIG. 1C is a cross-sectional view taken along line B-B′ of FIG. 1A. FIG. 1D is a cross-sectional view taken along line C-C′ of FIG. 1A. FIG. 1E is an enlarged view of region ‘E1’ of FIG. 1A. FIG. 1F is an enlarged view of region ‘E2’ of FIG. 1B. FIG. 1G is an enlarged view of region ‘E3’ of FIG. 1C. FIG. 1H is an enlarged view of region ‘E4’ of FIG. 1D.

Referring to FIGS. 1A to 1D, the semiconductor device may include a substrate 10. Logic cells may be disposed on the substrate 10. In the present disclosure, the logic cell may mean a logic element (e.g., AND, OR, XOR, XNOR, an inverter, or the like) that performs a specific function. The logic cell may include transistors for constituting the logic element.

The substrate 10 may be a semiconductor substrate, an insulator substrate, or a silicon-on-insulator (SOI) substrate. For example, the semiconductor substrate may include silicon, germanium, silicon-germanium, GaP, or GaAs. The substrate 10 may have a form of a plate extending along a plane extending in a first direction D1 and a second direction D2. The first direction D1 and the second direction D2 may cross each other. For example, the first direction D1 and the second direction D2 may be horizontal directions perpendicular to each other. According to some example embodiments, a crystal plane of an upper surface of the substrate 10 may be a {100} plane.

The substrate 10 may include active patterns AP. The active patterns AP may extend in the first direction D1. The active patterns AP may be arranged spaced apart from each other in the second direction D2. The active patterns AP may be upper portions of the substrates 10 protruding in a third direction D3. The third direction D3 may cross the first direction D1 and the second direction D2. For example, the third direction D3 may be a vertical direction of the first direction D1 and the second direction D2.

According to some example embodiments, the semiconductor device may not include the substrate 10 and the active patterns AP, and insulating patterns may be provided in positions at which the active patterns AP are provided.

An element isolation layer ST may be provided on the substrate 10. The element isolation layer ST may surround the active patterns AP. The element isolation layer ST may fill a space between the active patterns AP. The element isolation layer ST may include an insulating material. For example, the element isolation layer ST may include oxide. According to some example embodiments, the element isolation layer ST may be a multiple layer including a plurality of insulating layers.

Lower channel structures CH1 may be provided. The lower channel structure CH1 may overlap the active pattern AP in the third direction D3. A plurality of lower channel structures CH1 overlapping one active pattern AP in the third direction D3 may be arranged spaced apart from each other in the first direction D1. The lower channel structure CH1 may include lower semiconductor patterns SP1 overlapping each other in the third direction D3. The lower semiconductor patterns SP1 may include, for example, silicon or silicon-germanium. A number of the lower semiconductor patterns SP1 included in the lower channel structure CH1 may not be limited to what is illustrated. According to some example embodiments, the lower channel structure CH1 may include two or four or more lower semiconductor patterns SP1. According to some example embodiments, a channel direction of the lower semiconductor pattern SP1 may be a <110> direction.

Lower source/drain patterns SD1 may be provided on the active patterns AP. The lower source/drain pattern SD1 may overlap the active pattern AP in the third direction D3. A plurality of lower source/drain patterns SD1 overlapping one active pattern AP in the third direction D3 may be arranged spaced apart from each other in the first direction D1. The lower source/drain pattern SD1 may be disposed between the lower channel structures CH1. The lower source/drain pattern SD1 may be connected to the lower semiconductor pattern SP1 of the lower channel structures CH1. The lower channel structure CH1 may be disposed between the lower source/drain patterns SD1.

The lower source/drain pattern SD1 may be an epitaxial pattern formed in a selective epitaxial growth (SEG) process. The lower source/drain pattern SD1 may include silicon (Si) or silicon-germanium (SiGe). The lower source/drain pattern SD1 may be doped with an impurity to have a first conductive type.

Lower gate electrodes GE1 and GE2 extending in the second direction D2 may be provided. The lower gate electrode GEL or GE2 may cross the lower channel structure CH1. The lower gate electrode GEL or GE2 may overlap the lower channel structure CH1 and the active pattern AP in the third direction D3. The lower gate electrodes GEL and GE2 may be arranged along the first direction D1. The lower source/drain pattern SD1 may be disposed between the lower gate electrodes GEL and GE2. The lower gate electrode GE1 or GE2 may include parts disposed between the lower semiconductor patterns SP1 and parts disposed between a lowermost one of the lower semiconductor patterns SP1 and the active pattern AP. The lower gate electrode GE1 or GE2 may include a conductive material.

The lower gate electrode GEL or GE2, and the lower semiconductor patterns SP1 surrounded by the lower gate electrode GEL or GE2 may constitute a three-dimensional field effect transistor (e.g., a multi-bridge channel field-effect transistor (MBCFET) or a gate-all-around field-effect transistor GAAFET).

Lower gate insulating layers GI1 may be provided. The lower gate insulating layer GI1 may be in contact with the lower gate electrode GEL or GE2. The lower gate insulating layer GI1 may space the lower gate electrode GEL or GE2 apart from the lower semiconductor patterns SP1 and the lower source/drain patterns SD1. The lower gate insulating layer GI1 may surround the lower semiconductor patterns SP1. The lower gate insulating layer GI1 may include an insulating material. For example, the lower gate insulating layer GI1 may include oxide.

Lower gate spacers GS1 may be provided. A pair of lower gate spacers GS1 may be provided on both sides of the lower gate electrode GEL or GE2. The lower gate spacers GS1 may extend in the second direction D2. The lower gate spacers GS1 may include an insulating material.

Lower filling insulating layers 11 may be provided. The lower filling insulating layer 11 may be provided between the lower source/drain patterns SD1. The lower filling insulating layer 11 may be provided on the element isolation layer ST. The lower filling insulating layers 11 may be spaced apart from each other in the second direction D2. The lower source/drain pattern SD1 may be disposed between the lower filling insulating layers 11. The lower filling insulating layers 11 may include an insulating material. For example, the lower filling insulating layers 11 may include nitride. According to some example embodiments, the lower filling insulating layers 11 may be a multiple layer including a plurality of insulating layers.

Lower active contacts AC1 and AC2 may be provided. The lower active contact AC1 or AC2 may be electrically connected to the lower source/drain pattern SD1. The lower active contact AC1 or AC2 may be in contact with the lower source/drain pattern SD1. The lower active contact AC1 or AC2 may be disposed on the lower source/drain pattern SD1. The lower active contact AC1 or AC2 may be disposed between the lower filling insulating layers 11. The lower active contact AC1 or AC2 may be disposed between the lower gate electrodes GE1 and GE2. The lower active contact AC1 or AC2 may include a conductive material.

A mask layer 20 may be provided. The mask layer 20 may be provided on the lower filling insulating layers 11, the lower active contacts AC1 and AC2 and the lower gate electrodes GE1 and GE2. The mask layer 20 may be in contact with the lower filling insulating layers 11, the lower active contacts AC1 and AC2 and the lower gate electrodes GE1 and GE2. The mask layer 20 may include an insulating material. The mask layer 20 may include a material having etching selectivity with respect to a material included by the lower active contact AC1 or AC2 and a material included by the lower gate electrode GEL or GE2. For example, the lower active contact AC1 or AC2 and the lower gate electrode GEL or GE2 may include metal, and the mask layer 20 may include silicon nitride.

An interlayer structure 50 may be provided on the mask layer 20. The interlayer structure 50 may include a first interlayer insulating layer 51 on the mask layer 20, a second interlayer insulating layer 52 on the first interlayer insulating layer 51 and a semiconductor layer 53 on the second interlayer insulating layer 52. The mask layer 20 may be provided between the interlayer structure 50 and the lower channel structure CH1. The mask layer 20 may be provided between the interlayer structure 50 and the lower active contact AC1 or AC2. The mask layer 20 may be provided between the interlayer structure 50 and the lower gate electrode GE1 or GE2. The mask layer 20 may be provided between the interlayer structure 50 and the lower source/drain pattern SD1.

The first interlayer insulating layer 51 and the second interlayer insulating layer 52 may include the same insulating material. The first interlayer insulating layer 51 and the second interlayer insulating layer 52 may include insulating materials capable of being bonded to each other. The first interlayer insulating layer 51 and the second interlayer insulating layer 52 may include an insulating material having a relatively great adhesive force. For example, the first and second interlayer insulating layers 51 and 52 may include oxide.

The insulating material included in the first interlayer insulating layer 51 and the second interlayer insulating layer 52 may have etching selectivity with respect to an insulating material included in the mask layer 20. For example, the first and second interlayer insulating layers 51 and 52 may include oxide, and the mask layer 20 may include nitride.

The semiconductor layer 53 may include a semiconductor material. For example, the semiconductor layer 53 may include silicon or silicon-germanium. According to some example embodiments, a crystal plane of an upper surface of the semiconductor layer 53 may be a {110} plane. According to some example embodiments, the interlayer structure 50 may not include the semiconductor layer 53. According to some example embodiments, the interlayer structure 50 may be a single insulating layer.

Upper channel structures CH2 may be provided. The mask layer 20 and the interlayer structure 50 may be provided between the upper channel structures CH2 and the lower channel structures CH1. The upper channel structure CH2 may overlap the lower channel structures CH1 in the third direction D3. The upper channel structure CH2 may include upper semiconductor patterns SP2 overlapping each other in the third direction D3. The upper semiconductor patterns SP2 may include, for example, silicon or silicon-germanium. A number of the upper semiconductor patterns SP2 included by the upper channel structure CH2 may not be limited to what is illustrated. According to some example embodiments, the upper channel structure CH2 may include two or four or more upper semiconductor patterns SP2. According to some example embodiments, a channel direction of the upper semiconductor pattern SP2 may be a <110> direction.

Upper source/drain patterns SD2 may be provided on the semiconductor layer 53 of the interlayer structure 50. Two upper source/drain patterns SD2 may overlap one lower source/drain pattern SD1 in the third direction D3. Two upper source/drain patterns SD2 may be disposed between the upper channel structures CH2 adjacent to each other in the first direction D1. The mask layer 20 and the interlayer structure 50 may be provided between the lower source/drain patterns SD1 and the upper source/drain patterns SD2. The upper source/drain patterns SD2 may be connected to the upper semiconductor patterns SP2 of the upper channel structure CH2.

The upper source/drain pattern SD2 may be an epitaxial pattern formed in a selective epitaxial growth (SEG) process. The upper source/drain pattern SD2 may include silicon (Si) or silicon-germanium (SiGe). The upper source/drain pattern SD2 may be doped with an impurity to have a second conductive type different from the first conductive type. For example, the first conductive type may be an N-type, and the second conductive type may be a P-type.

Upper gate electrodes GE3 extending in the second direction D2 may be provided. The upper gate electrode GE3 may cross the upper channel structure CH2. The upper gate electrode GE3 may overlap the upper channel structure CH2 in the third direction D3. The upper gate electrodes GE3 may be arranged along the first direction D1. The upper gate electrode GE3 may be disposed between the upper source/drain patterns SD2. The upper gate electrodes GE3 may include parts disposed between the upper semiconductor patterns SP2 and parts disposed between a lowermost one of the upper semiconductor patterns SP2 and the semiconductor layer 53. The upper gate electrodes GE3 may include a conductive material.

The upper gate electrode GE3 and the upper semiconductor patterns SP2 surrounded by the upper gate electrode GE3 may constitute a three-dimensional field effect transistor (e.g., a MBCFET or a GAAFET).

Upper gate insulating layers GI2 may be provided. The upper gate insulating layer GI2 may be in contact with the upper gate electrode GE3. The upper gate insulating layer GI2 may space the upper gate electrode GE3 apart from the upper semiconductor patterns SP2 and the upper source/drain patterns SD2. The upper gate insulating layer GI2 may surround the upper semiconductor patterns SP2. The upper gate insulating layer GI2 may include an insulating material. For example, the upper gate insulating layer GI2 may include oxide.

Upper gate spacers GS2 may be provided. A pair of upper gate spacers GS2 may be provided on both sides of the upper gate electrode GE3. The upper gate spacers GS2 may extend in the second direction D2. The upper gate spacers GS2 may include an insulating material.

Upper filling insulating layers 12 may be provided. The upper filling insulating layers 12 may be provided on the semiconductor layer 53 of the interlayer structure 50. The upper filling insulating layers 12 may include an insulating material. For example, the upper filling insulating layers 12 may include nitride. According to some example embodiments, the upper filling insulating layers 12 may be a multiple layer including a plurality of insulating layers.

Upper active contacts AC3 may be provided. The upper active contact AC3 may be disposed between the upper source/drain patterns SD2 adjacent to each other in the first direction D1. The upper active contact AC3 may be electrically connected to the upper source/drain pattern SD2. One upper active contact AC3 may be in contact with two upper source/drain patterns SD2. The upper active contact AC3 may be disposed between the upper filling insulating layers 12. The upper active contact AC3 may be disposed between the upper gate electrodes GE3. The upper active contact AC3 may be disposed between the upper channel structures CH2. The upper active contact AC3 may include a conductive material.

Through active contacts TC may be provided. The through active contact TC may be electrically connected to the lower source/drain pattern SD1 and the upper source/drain pattern SD2. The through active contact TC may be in contact with a first lower active contact AC1 to be described later. One through active contact TC may be in contact with two upper source/drain patterns SD2. The through active contact TC may be disposed between the upper filling insulating layers 12. The through active contact TC may be disposed between the upper gate electrodes GE2. The through active contact TC may be disposed between the upper channel structures CH2. The through active contact TC may penetrate the first interlayer insulating layer 51, the second interlayer insulating layer 52 and the semiconductor layer 53 of the interlayer structure 50. The through active contacts TC may include a conductive material.

An upper insulating layer 61 may be provided on the upper active contacts AC3, the through active contacts TC, the upper filling insulating layers 12 and the upper gate electrodes GE3. The upper insulating layer 61 may include an insulating material. According to some example embodiments, the upper insulating layer 61 may be a multiple layer including a plurality of insulating layers.

Contacts 62 penetrating the upper insulating layer 61 may be provided. The contact 62 may be provided on the upper active contact AC3, the through active contact TC or the upper gate electrode GE3. The contact 62 may be electrically connected to the upper active contact AC3, the through active contact TC or the upper gate electrode GE3. The contacts 62 may include a conductive material.

A gate connection contact 63 penetrating the interlayer structure 50 may be provided. The gate connection contact 63 may be surrounded by the interlayer structure 50. The gate connection contact 63 may be in contact with the upper gate electrode GE3 and a first lower gate electrode GE1 to be described later. The gate connection contact 63 may electrically connect the first lower gate electrode GE1 and the upper gate electrode GE3. The gate connection contact 63 may include a conductive material.

Lower gate separation layers 65 may be provided. The lower gate separation layers 65 may be provided on the element isolation layer ST. The lower gate electrode GEL or GE2 may be provided between the lower gate separation layers 65. The lower gate electrodes GE1 and GE2 may be spaced apart from each other by the lower gate separation layer 65. The lower gate separation layers 65 may include an insulating material.

Upper gate separation layers 66 may be provided. The upper gate separation layer 66 may be provided on the lower gate separation layer 65. The upper gate electrode GE3 may be provided between the upper gate separation layers 66. The upper gate electrodes GE3 may be spaced apart from each other by the upper gate separation layer 66. The upper gate separation layers 66 may include an insulating material.

The lower gate electrodes GE1 and GE2 may include first lower gate electrodes GE1 and second lower gate electrodes GE2. The first lower gate electrode GE1 may include a gate conductive portion 31 and a gate via portion 32. The gate via portion 32 may be provided on the gate conductive portion 31. The gate via portion 32 may be disposed at a higher level than the gate conductive portion 31.

The gate conductive portion 31 may overlap the lower semiconductor patterns SP1 of the lower channel structure CH1 in the third direction D3. The gate conductive portion 31 may include parts disposed between the lower semiconductor patterns SP1 and parts disposed between a lowermost one of the lower semiconductor patterns SP1 and the active pattern AP. The gate conductive portion 31 may be in contact with the lower gate separation layers 65.

The second lower gate electrode GE2 may be disposed at the same level as the gate conductive portion 31. The second lower gate electrode GE2 may be disposed at a lower level than the gate via portion 32.

The lower active contacts AC1 and AC2 may include first lower active contacts AC1 and second lower active contacts AC2. The first lower active contact AC1 may include an active conductive portion 41 and an active via portion 42. The active via portion 42 may be provided on the active conductive portion 41. The active via portion 42 may be disposed at a higher level than the active conductive portion 41.

The second lower active contacts AC2 may be disposed at the same level as the active conductive portion 41. The second lower active contacts AC2 may be disposed at a lower level than the active via portion 42.

A lower surface 20_L of the mask layer 20 may be in contact with an upper surface of the lower filling insulating layers 11, an upper surface of the second lower gate electrode GE2 and an upper surface of the second lower active contact AC2.

Referring to FIGS. 1E, IF, 1G and 1H, a width W1 in the second direction D2 of the gate conductive portion 31 may be greater than a width W2 in the second direction D2 of the gate via portion 32. A width W3 in the second direction D2 of the active conductive portion 41 may be greater than a width W4 in the second direction D2 of the active via portion 42.

The active conductive portion 41 may include a first part 41a, a second part 41b spaced apart from the first part 41a in the second direction D2 and a third part 41c between the first part 41a and the second part 41b. The third part 41c of the active conductive portion 41 may overlap the active via portion 42 in the third direction D3. The first part 41a and the second part 41b of the active conductive portion 41 may not overlap the active via portion 42 in the third direction D3.

A width W11 in the second direction D2 of the first part 41a of the active conductive portion 41 may be smaller than a width W12 in the second direction D2 of the second part 41b of the active conductive portion 41. A distance between the first part 41a of the active conductive portion 41 and the gate via portion 32 may be greater than a distance between the second part 41b of the active conductive portion 41 and the gate via portion 32.

The active conductive portion 41 may include a first sidewall 41_S1 adjacent to the gate via portion 32 and a second sidewall 41_S2 opposed to the first sidewall 41_S1. The first sidewall 41_S1 and the second sidewall 41_S2 of the active conductive portion 41 may be parallel to the first direction D1. A distance L1 in the second direction D2 between the second sidewall 41_S2 of the active conductive portion 41 and the third part 41c of the active conductive portion 41 may be smaller than a distance L2 in the second direction D2 between the first sidewall 41_S1 of the active conductive portion 41 and the third part 41c of the active conductive portion 41. The distance L1 in the second direction D2 between the second sidewall 41_S2 of the active conductive portion 41 and the active via portion 42 may be smaller than the distance L2 in the second direction D2 between the first sidewall 41_S1 of the active conductive portion 41 and the active via portion 42.

A lower surface 41_L of the active conductive portion 41 may be in contact with an upper surface SD1_U of the lower source/drain pattern SD1. The lower surface 41_L of the active conductive portion 41 may include lower surfaces of the first to third parts 41a, 41b and 41c of the active conductive portion 41. The first sidewall 41_S1 of the active conductive portion 41 may be in contact with the lower filling insulating layer 11. The second sidewall 41_S2 of the active conductive portion 41 may be in contact with the lower filling insulating layer 11.

The mask layer 20 may include a first sidewall 20_S1, a second sidewall 20_S2, an upper surface 20_U, a lower surface 20_L, a first curved surface 20_C1 and a second curved surface 20_C2. The first curved surface 20_C1 of the mask layer 20 may connect the first sidewall 20_S1 and the upper surface 20_U of the mask layer 20. The second curved surface 20_C2 of the mask layer 20 may connect the second sidewall 20_S2 and the upper surface 20_U of the mask layer 20. The first curved surface 20_C1 of the mask layer 20 may be disposed between the first sidewall 20_S1 and the upper surface 20_U of the mask layer 20. The second curved surface 20_C2 of the mask layer 20 may be disposed between the second sidewall 20_S2 and the upper surface 20_U of the mask layer 20.

The first sidewall 20_S1 of the mask layer 20 may connect the first curved surface 20_C1 and the lower surface 20_L of the mask layer 20. The second sidewall 20_S2 of the mask layer 20 may connect the second curved surface 20_C2 and the lower surface 20_L of the mask layer 20. The first sidewall 20_S1 of the mask layer 20 may be disposed between the first curved surface 20_C1 and the lower surface 20_L of the mask layer 20. The second sidewall 20_S2 of the mask layer 20 may be disposed between the second curved surface 20_C2 and the lower surface 20_L of the mask layer 20.

The first interlayer insulating layer 51 may include a first interposed portion IN1 surrounded by the first curved surface 20_C1 of the mask layer 20. The first interposed portion IN1 may be disposed at a lower level than the upper surface 20_U of the mask layer 20.

The through active contact TC may include a lower portion TC_L and an upper portion TC_U. The upper portion TC_U of the through active contact TC may be in contact with the upper source/drain patterns SD2. The lower portion TC_L of the through active contact TC may be surrounded by the first interposed portion IN1 and the first curved surface 20_C1 of the mask layer 20. The first interposed portion IN1 may be disposed between the lower portion TC_L of the through active contact TC and the first curved surface 20_C1 of the mask layer 20. The lower portion TC_L of the through active contact TC may be disposed at a lower level than the upper surface 20_U of the mask layer 20.

A sidewall 42_S of the active via portion 42 may be in contact with the first sidewall 20_S1 of the mask layer 20. The first sidewall 20_S1 of the mask layer 20 may surround the active via portion 42. An upper surface 42_U of the active via portion 42 may be in contact with a lower surface TC_LL of the lower portion TC_L of the through active contact TC and a lower surface IN1_L of the first interposed portion IN1. The upper surface 42_U of the active via portion 42 may have a lower level than the upper surface 20_U of the mask layer 20.

The first interposed portion IN1 may include a curved surface IN1_C in contact with the first curved surface 20_C1 of the mask layer 20. The lower portion TC_L of the through active contact TC may include a sidewall TC_LS in contact with the first curved surface 20_C1 of the mask layer 20. The sidewall TC_LS of the lower portion TC_L of the through active contact TC may be curved. A width in the second direction D2 of the lower portion TC_L of the through active contact TC may become smaller as a level thereof becomes lower.

An upper surface 41a_U of the first part 41a of the active conductive portion 41 may be in contact with the lower surface 20_L of the mask layer 20. An upper surface 41b_U of the second part 41b of the active conductive portion 41 may be in contact with the lower surface 20_L of the mask layer 20. The upper surface 41a_U of the first part 41a of the active conductive portion 41 may connect the second sidewall 41_S2 of the active conductive portion 41 and the sidewall 42_S of the active via portion 42. The upper surface 41b_U of the second part 41b of the active conductive portion 41 may connect the first sidewall 41_S1 of the active conductive portion 41 and the sidewall 42_S of the active via portion 42. An upper surface of the active conductive portion 41 may include an upper surface 41b_U of the second part 41b of the active conductive portion 41 and an upper surface 41a_U of the first part 41a of the active conductive portion 41.

The first interlayer insulating layer 51 may include a second interposed portion IN2 surrounded by the second curved surface 20_C2 of the mask layer 20. The second interposed portion IN2 may be disposed at a lower level than the upper surface 20_U of the mask layer 20. A lower portion of the gate connection contact 63 may be surrounded by the second interposed portion IN2 and the second curved surface 20_C2 of the mask layer 20. The second interposed portion IN2 may be disposed between the lower portion of the gate connection contact 63 and the second curved surface 20_C2 of the mask layer 20.

A sidewall 32_S of the gate via portion 32 may be in contact with the second sidewall 20_S2 of the mask layer 20. The second sidewall 20_S2 of the mask layer 20 may surround the gate via portion 32. An upper surface 32_U of the gate via portion 32 may be in contact with a lower surface of the gate connection contact 63. The upper surface 32_U of the gate via portion 32 may have a lower level than the upper surface 20_U of the mask layer 20.

The second interposed portion IN2 may include a curved surface IN2_C in contact with the second curved surface 20_C2 of the mask layer 20. An upper surface 31_U of the gate conductive portion 31 may be in contact with the lower surface 20_L of the mask layer 20.

The gate via portion 32 may be disposed at a higher level than the lower surface 20_L of the mask layer 20. The sidewall 32_S and the upper surface 32_U of the gate via portion 32 may be disposed at a higher level than the lower surface 20_L of the mask layer 20.

The active via portion 42 may be disposed at a higher level than the lower surface 20_L of the mask layer 20. The sidewall 42_S and the upper surface 42_U of the active via portion 42 may be disposed at a higher level than the lower surface 20_L of the mask layer 20.

Because in the semiconductor device according to some example embodiments, the first lower gate electrode GE1 includes the gate via portion 32, a separate conductive contact or conductive line for connecting the first lower gate electrode GE1 and the gate connection contact 63 may be omitted. Accordingly, a size of the semiconductor device may be reduced or minimized, and/or cost for manufacturing the semiconductor device may be saved.

Because in the semiconductor device according to some example embodiments, the first lower active contact AC1 includes the active via portion 42, a conductive contact or conductive line for connecting the first lower active contact AC1 and the through active contact TC may be omitted. Accordingly, the size of the semiconductor device may be reduced or minimized, and/or cost for manufacturing the semiconductor device may be saved.

Because in the semiconductor device according to some example embodiments, a distance between the active via portion 42 and the second sidewall 41_S2 of the active conductive portion 41 is smaller than a distance between the active via portion 42 and the first sidewall 41_S1 of the active conductive portion 41, a distance between the active via portion 42 and the gate via portion 32 may be relatively great, and a short circuit between the active via portion 42 and the gate via portion 32 may be reduced or prevented.

Because in the semiconductor device according to some example embodiments, the active via portion 42 and the gate via portion 32 have relatively small widths, the distance between the active via portion 42 and the gate via portion 32 may be relatively great, and the short circuit between the active via portion 42 and the gate via portion 32 may be reduced or prevented.

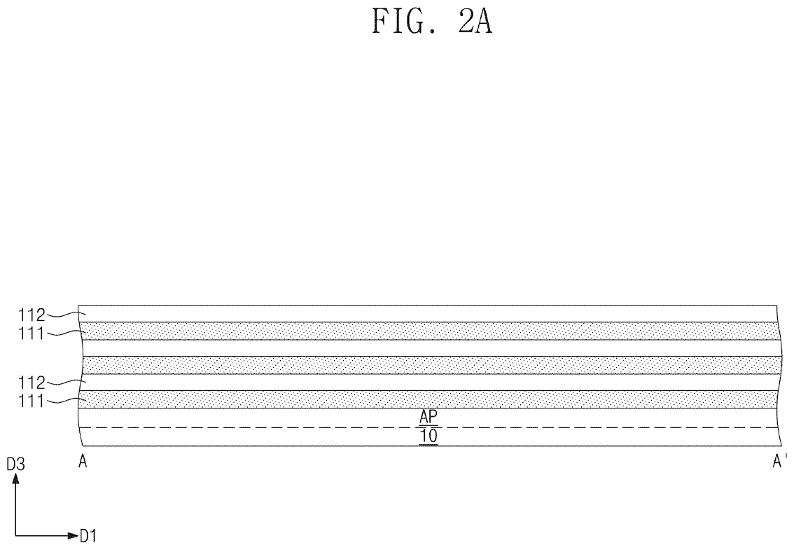

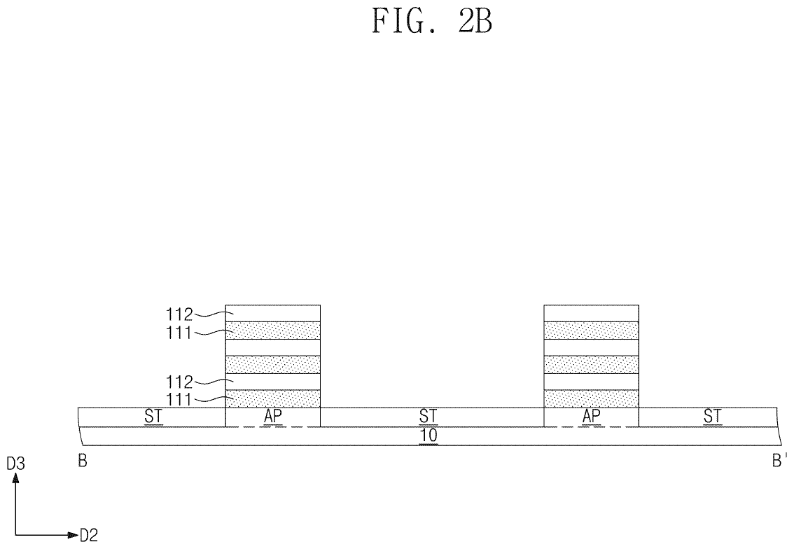

FIGS. 2A, 2B, 3A, 3B, 3C, 4A, 4B, 4C, 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 14A, 14B, 15A, 15B, and 15C are diagrams for describing a method for manufacturing a semiconductor device according to FIGS. 1A to 1H.

Referring to FIGS. 2A and 2B, a substrate 10 may be provided. Active patterns AP, lower sacrificial layers 111 and lower semiconductor layers 112 may be formed. Forming the active patterns AP, the lower sacrificial layers 111 and the lower semiconductor layers 112 may include alternately forming preliminary lower sacrificial layers and preliminary lower semiconductor layers on the substrate 10, forming a mask insulating pattern, and patterning the preliminary lower sacrificial layers, the preliminary lower semiconductor layers and the substrate 10 by using the mask insulating pattern as an etching mask.

The lower sacrificial layers 111 may be formed by patterning the preliminary lower sacrificial layers. The lower semiconductor layers 112 may be formed by patterning the preliminary lower semiconductor layers. The active pattern AP may be formed by patterning the substrate 10.

The lower sacrificial layer 111 may include a material having etching selectivity with respect to the lower semiconductor layer 112. For example, the lower sacrificial layer 111 may include silicon-germanium, and the lower semiconductor layer 112 may include silicon.

An element isolation layer ST may be formed.

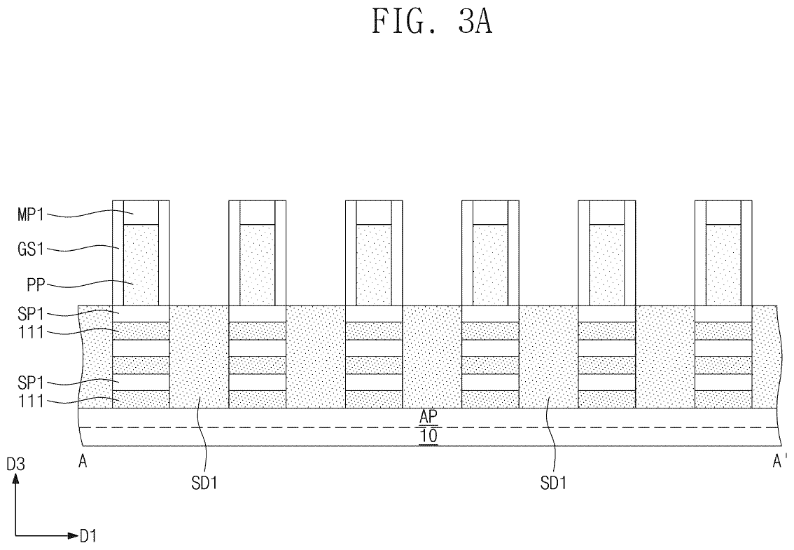

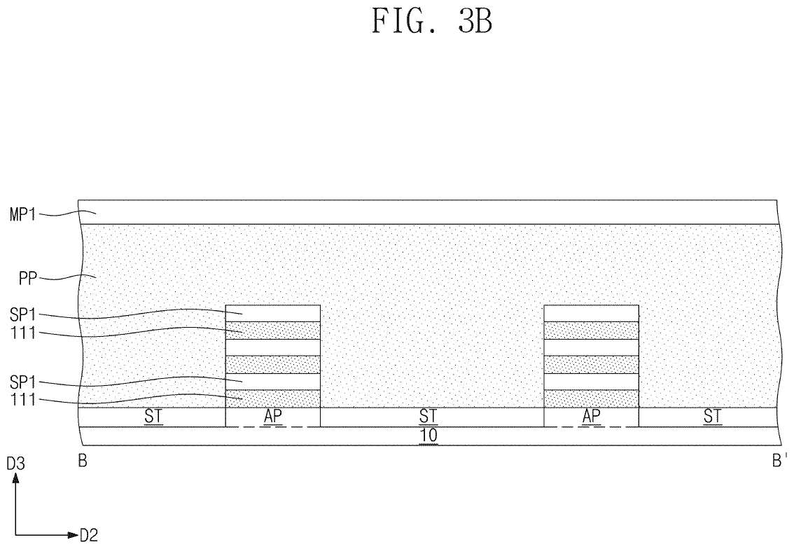

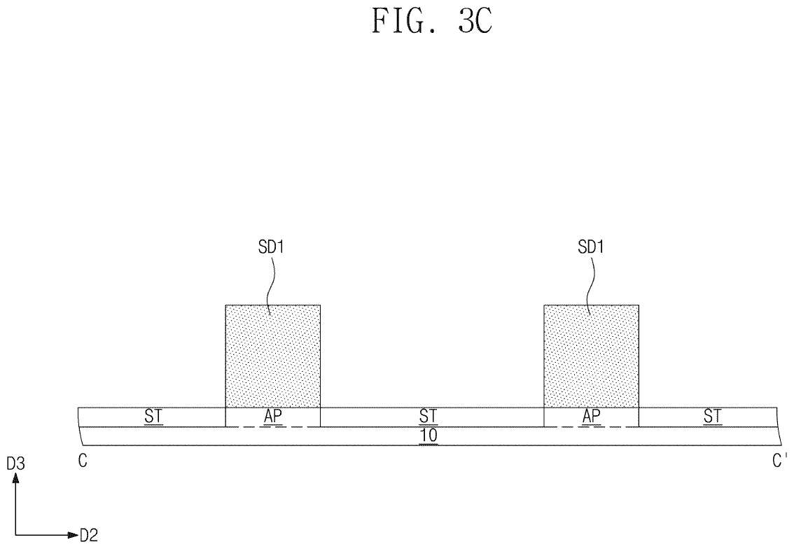

Referring to FIGS. 3A and 3B, sacrificial patterns PP and first mask patterns MP1 may be formed. Forming the sacrificial patterns PP and the first mask patterns MP1 may include forming a preliminary sacrificial pattern layer, forming the first mask patterns MP1 on the preliminary sacrificial pattern layer, and patterning the preliminary sacrificial pattern layer by using the first mask patterns MP1 as etching masks. The sacrificial patterns PP may be formed by patterning the preliminary sacrificial pattern layer. For example, the sacrificial patterns PP may include polysilicon. The first mask patterns MP1 may include an insulating material.

Lower gate spacers GS1 may be formed. The lower gate spacers GS1 may be formed on sidewalls of the sacrificial pattern PP and the first mask pattern MP1.

The lower sacrificial layers 111 and the lower semiconductor layers 112 may be etched by using the first mask patterns MP1 and the lower gate spacers GS1 as etching masks. The lower semiconductor patterns SP1 may be formed by etching the lower semiconductor layers 112. The lower semiconductor layer 112 may be divided into the lower semiconductor patterns SP1 arranged in the first direction D1.

Lower source/drain patterns SD1 may be formed. The lower source/drain patterns SD1 may be formed through an epitaxial growth process by using the lower semiconductor patterns SP1 and the etched lower sacrificial layers 111 as seeds.

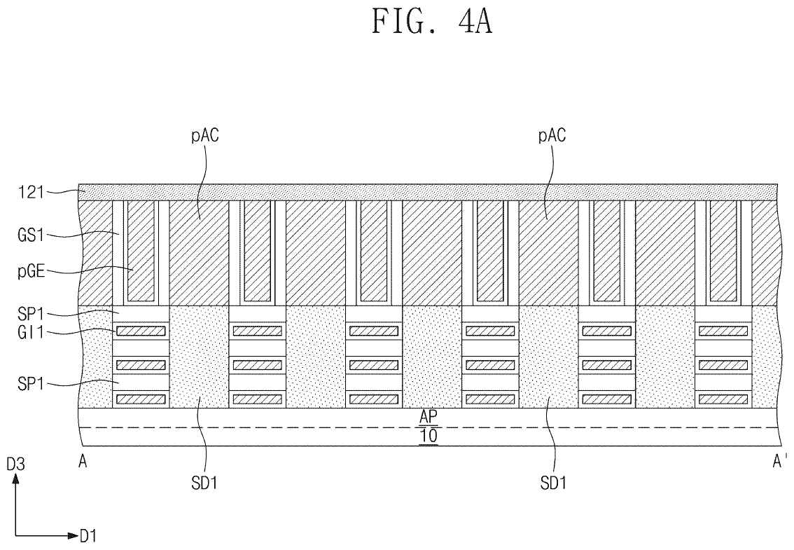

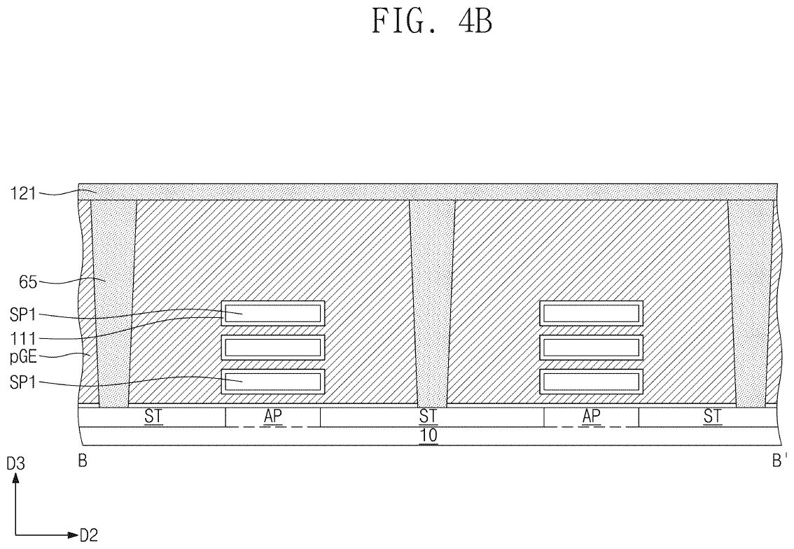

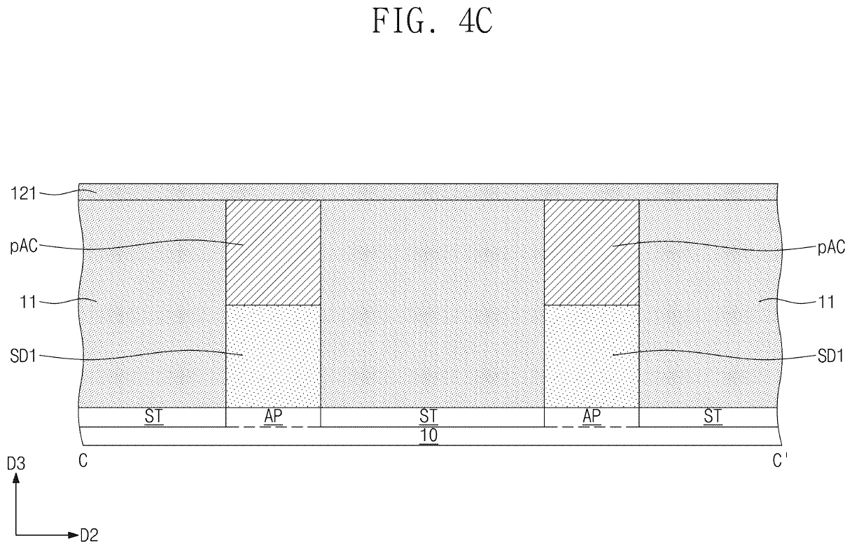

Referring to FIGS. 4A, 4B, and 4C, lower gate insulating layers GI1 and preliminary gate electrodes pGE may be formed. Forming the lower gate insulating layers GI1 and the preliminary gate electrodes pGE may include removing the first mask patterns MP1, the sacrificial patterns PP and the lower sacrificial layers 111, and forming the lower gate insulating layers GI1 and the preliminary gate electrodes pGE in empty spaces formed by removing the first mask patterns MP1, the sacrificial patterns PP and the lower sacrificial layers 111. The preliminary gate electrode pGE may include a conductive material.

Lower gate separation layers 65 may be formed. The preliminary gate electrode pGE may be separated into a plurality of preliminary gate electrodes pGE by the lower gate separation layers 65.

According to some example embodiments, a first insulating layer covering the lower source/drain patterns SD1 may be formed before forming the lower gate insulating layers GI1, the preliminary gate electrodes pGE and the lower gate separation layers 65, and may be removed after forming the lower gate insulating layers GI1, the preliminary gate electrodes pGE and the lower gate separation layers 65.

Lower filling insulating layers 11 and preliminary active contacts pAC may be formed. According to some example embodiments, forming the lower filling insulating layers 11 and the preliminary active contacts pAC may include forming a preliminary lower filling insulating layer on the lower source/drain patterns SD1, separating the preliminary lower filling insulating layer into the lower filling insulating layers 11, and forming the preliminary active contacts pAC between the lower filling insulating layers 11. The preliminary active contact pAC may be provided on the lower source/drain pattern SD1. The preliminary active contacts pAC may include a conductive material.

A cover insulating layer 121 may be formed on the preliminary gate electrode pGE, the preliminary active contact pAC and the lower filling insulating layer 11. The cover insulating layer 121 may include an insulating material. For example, the cover insulating layer 121 may include nitride.

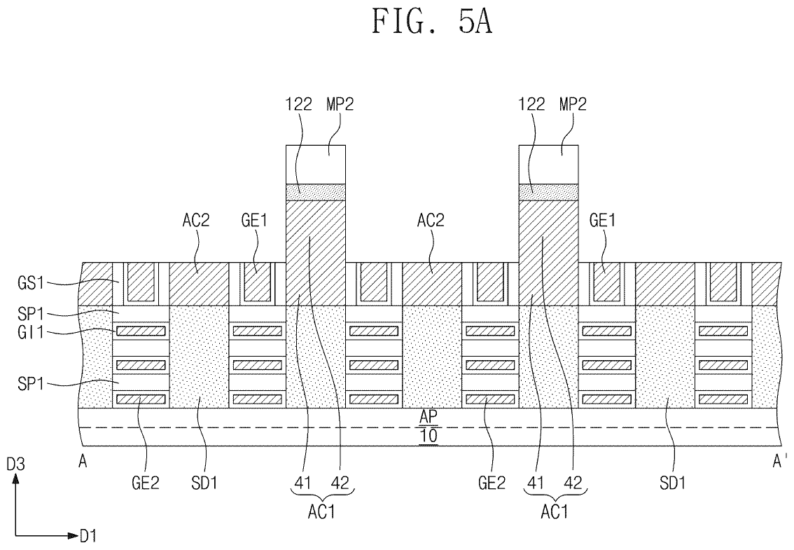

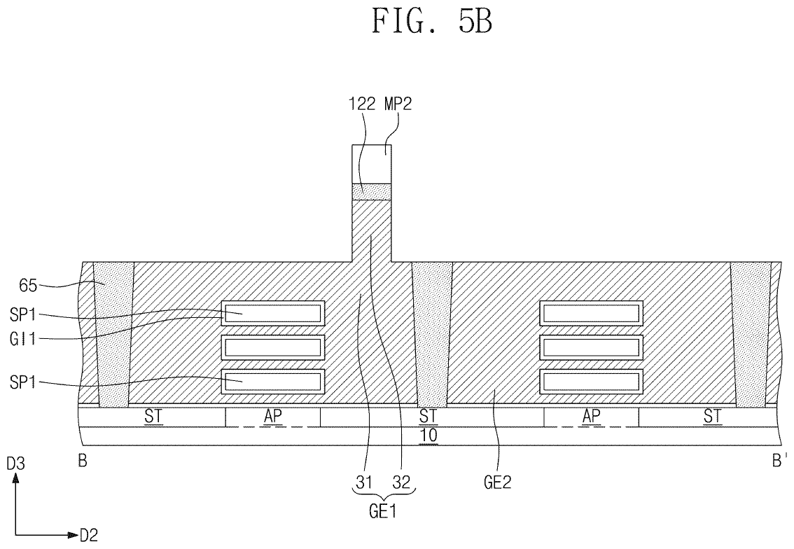

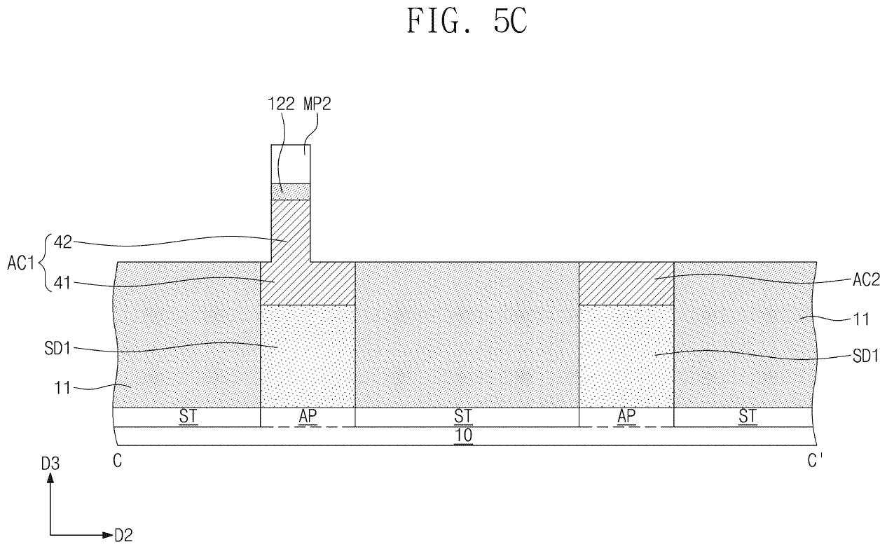

Referring to FIGS. 5A, 5B and 5C, second mask patterns MP2 may be formed on the cover insulating layer 121. The second mask patterns MP2 may include an insulating material.

The preliminary gate electrodes pGE, the lower gate separation layers 65, the preliminary active contacts pAC, the lower gate insulating layers GI1, the lower gate spacers GS1 and the lower filling insulating layers 11 may be etched.

According to some example embodiments, etching the preliminary gate electrodes pGE, the lower gate separation layers 65, the preliminary active contacts pAC, the lower gate insulating layers GI1, the lower gate spacers GS1 and the lower filling insulating layers 11 may include forming cover patterns 122 by etching the cover insulating layer 121 by using the second mask pattern MP2 as an etching mask, and etching the preliminary gate electrodes pGE, the lower gate separation layers 65, the preliminary active contacts pAC, the lower gate insulating layers GI1, the lower gate spacers GS1 and the lower filling insulating layers 11 by using the cover patterns 122 as etching masks.

According to some example embodiments, etching the preliminary gate electrodes pGE, the lower gate separation layers 65, the preliminary active contacts pAC, the lower gate insulating layers GI1, the lower gate spacers GS1 and the lower filling insulating layers 11 may include etching the cover insulating layer 121, the preliminary gate electrodes pGE, the lower gate separation layers 65, the preliminary active contacts pAC, the lower gate insulating layers GI1, the lower gate spacers GS1 and the lower filling insulating layers 11 by using the second mask pattern MP2 as an etching mask.

The preliminary gate electrodes pGE may be etched to form first lower gate electrodes GE1 and second lower gate electrodes GE2. The gate via portion 32 may be protected by at least one of the second mask pattern MP2 or the cover pattern 122 in the etching process.

The preliminary active contacts pAC may be etched to form first lower active contacts AC1 and second lower active contacts AC2. The active via portion 42 may be protected by at least one of the second mask pattern MP2 or the cover pattern 122 in the etching process.

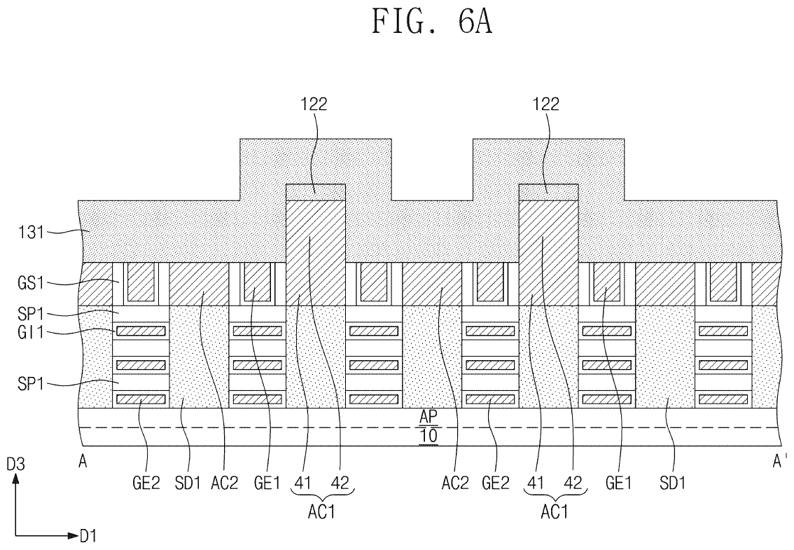

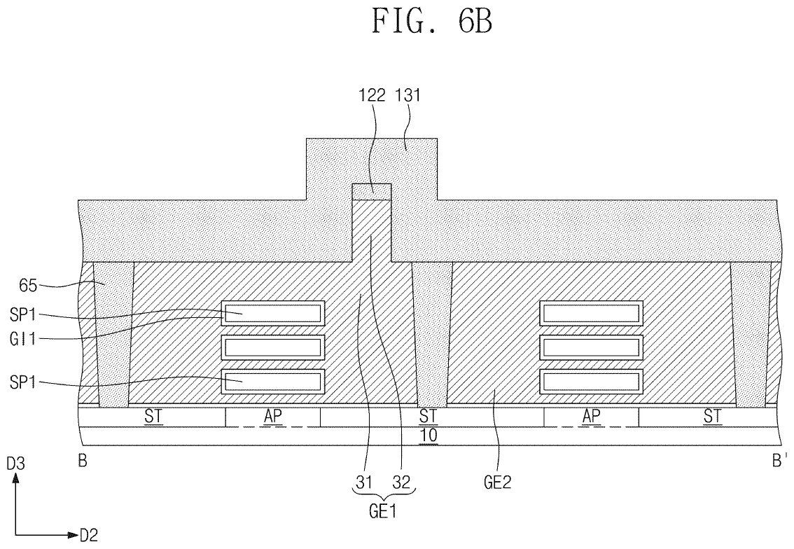

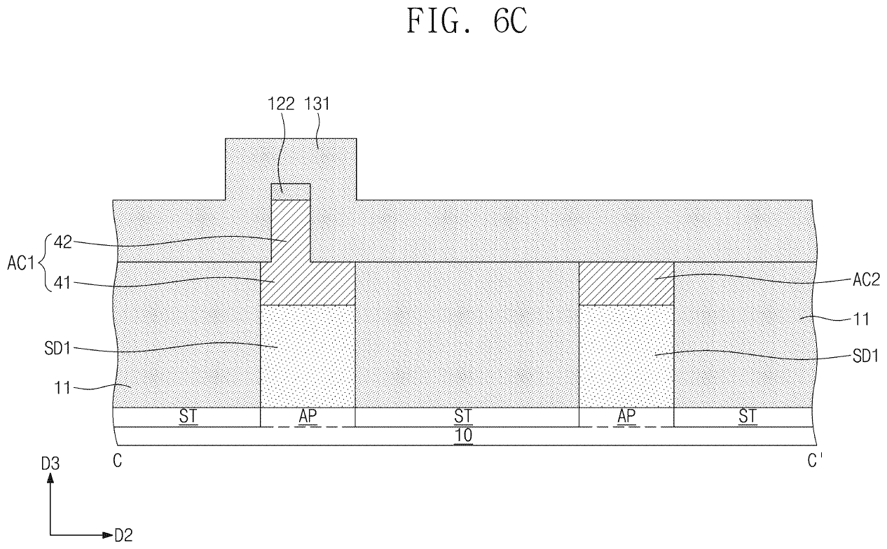

Referring to FIGS. 6A, 6B and 6C, the second mask patterns MP2 may be removed.

A preliminary mask layer 131 may be formed. The preliminary mask layer 131 may be formed on the first and second lower active contacts AC1 and AC2, the first and second lower gate electrodes GE1 and GE2, the lower filling insulating layers 11 and the cover patterns 122.

The preliminary mask layer 131 may include a material having etching selectivity with respect to a material included in the first and second lower active contacts AC1 and AC2 and a material included in the first and second lower gate electrodes GE1 and GE2. For example, the first and second lower active contacts AC1 and AC2 and the first and second lower gate electrodes GE1 and GE2 may include metal, and the preliminary mask layer 131 may include silicon nitride. The preliminary mask layer 131 may have a constant thickness.

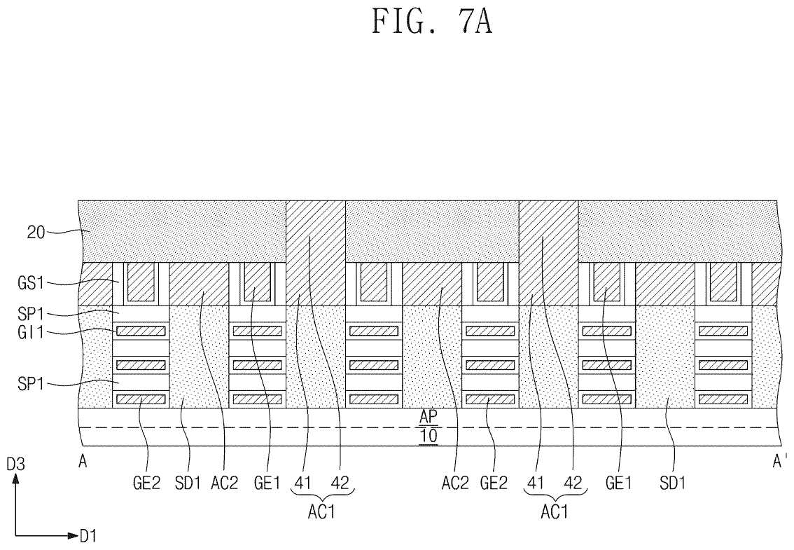

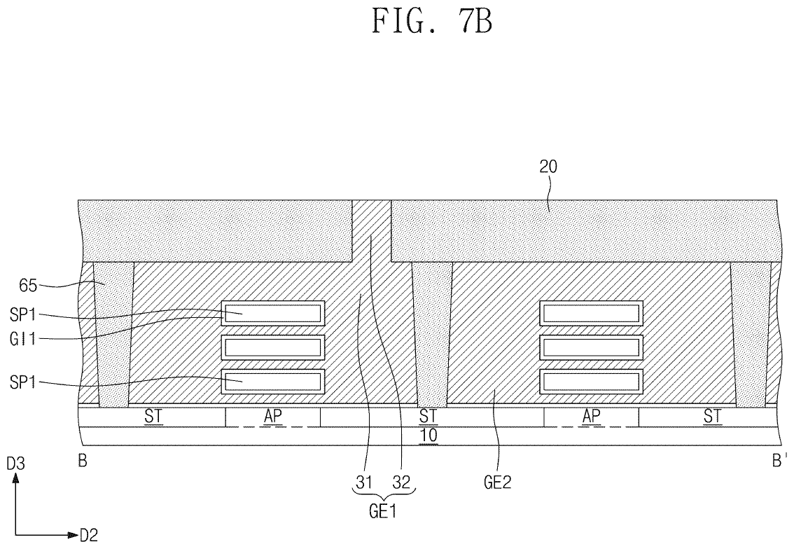

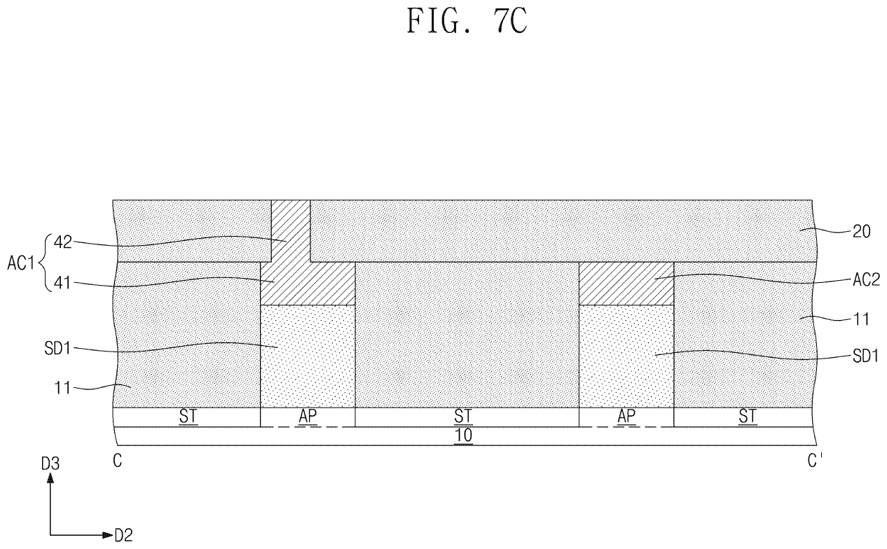

Referring to FIGS. 7A, 7B, and 7C, upper portions of the preliminary mask layers 131 and the cover patterns 122 may be removed. The upper portions of the preliminary mask layers 131 and the cover patterns 122 may be removed by, for example, a chemical mechanical polishing (CMP) process.

The upper portions of the preliminary mask layers 131 and the cover patterns 122 may be removed to expose the active via portion 42 and the gate via portion 32.

The preliminary mask layer 131 of which the upper portion is removed may be defined as the mask layer 20.

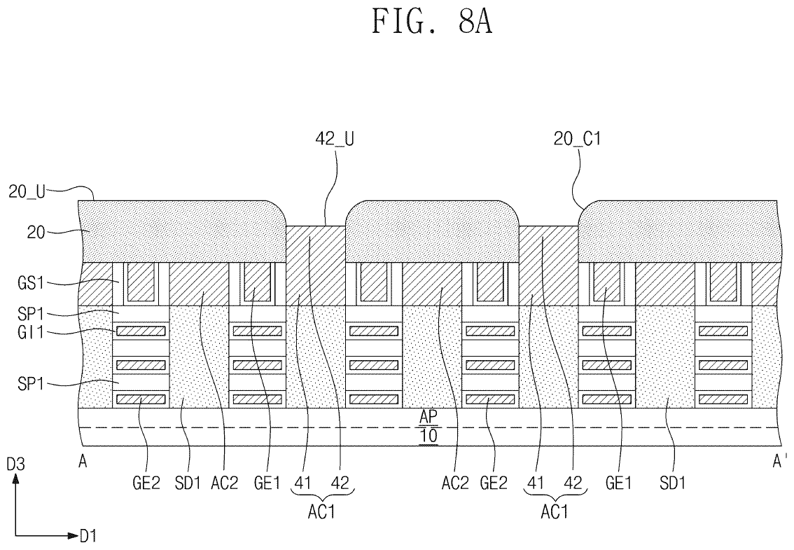

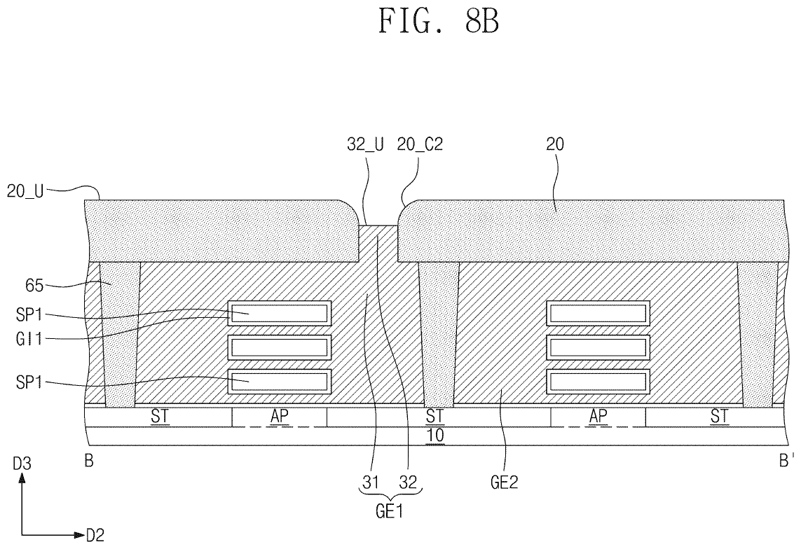

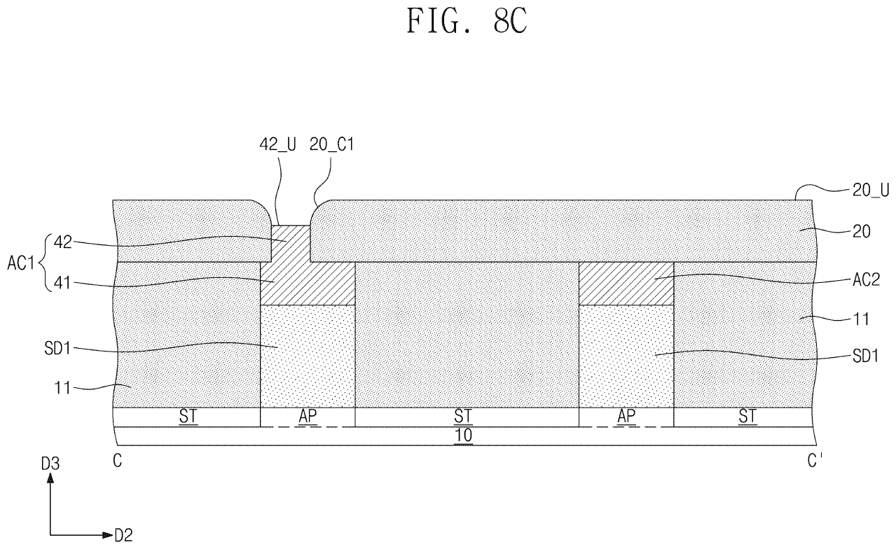

Referring to FIGS. 8A, 8B and 8C, the active via portion 42 and the gate via portion 32 may be etched. The gate via portion 32 and the active via portion 42 may be etched so that a level of an upper surface 42_U of the active via portion 42 and a level of an upper surface 32_U of the gate via portion 32 may be lower than a level of an upper surface 20_U of the mask layer 20.

The gate via portion 32 and the active via portion 42 may be etched together to form a first curved surface 20_C1 and a second curved surface 20_C2 on the mask layer 20.

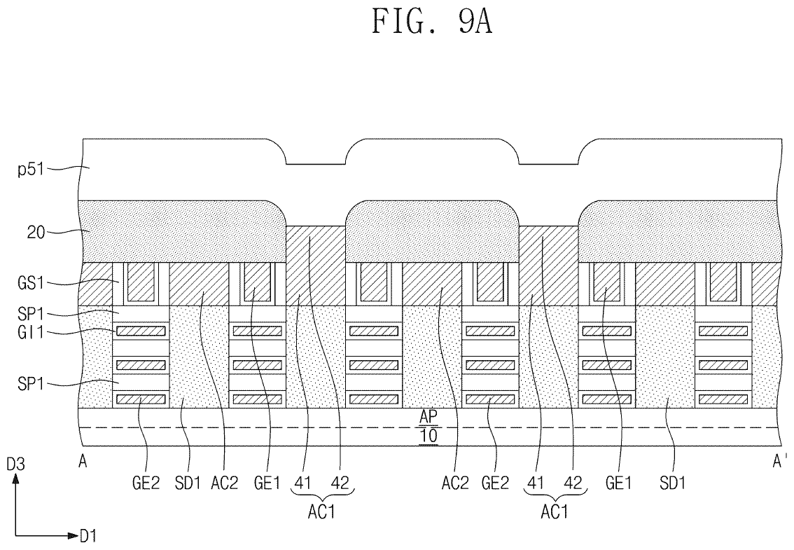

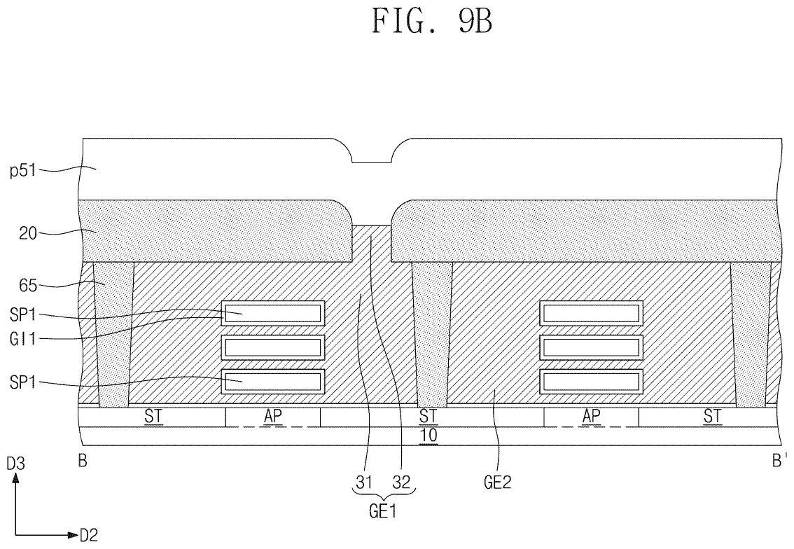

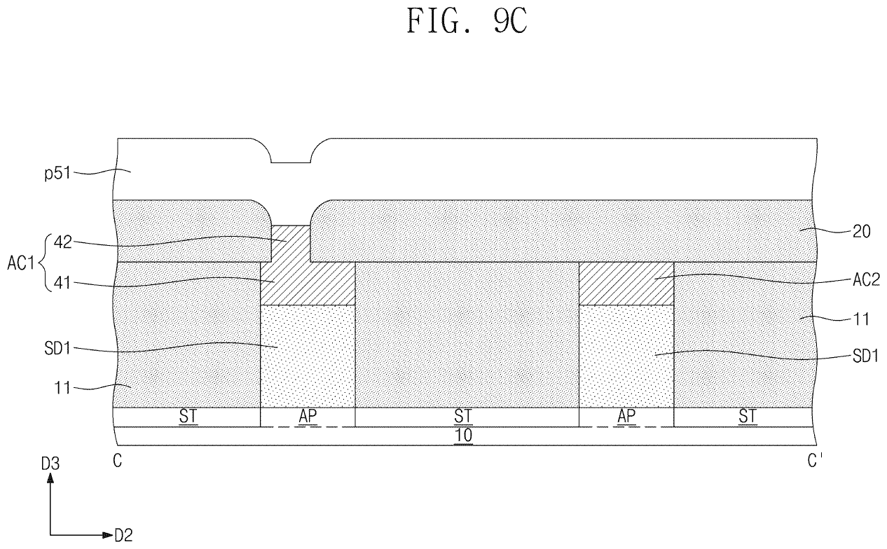

Referring to FIGS. 9A, 9B and 9C, a preliminary interlayer insulating layer p51 may be formed on the mask layer 20, the gate via portion 32 and the active via portion 42. The preliminary interlayer insulating layer p51 may have a constant thickness. The preliminary interlayer insulating layer p51 may have an insulating material having etching selectivity with respect to an insulating material included by the mask layer 20. For example, the preliminary interlayer insulating layer p51 may include oxide, and the mask layer 20 may include nitride.

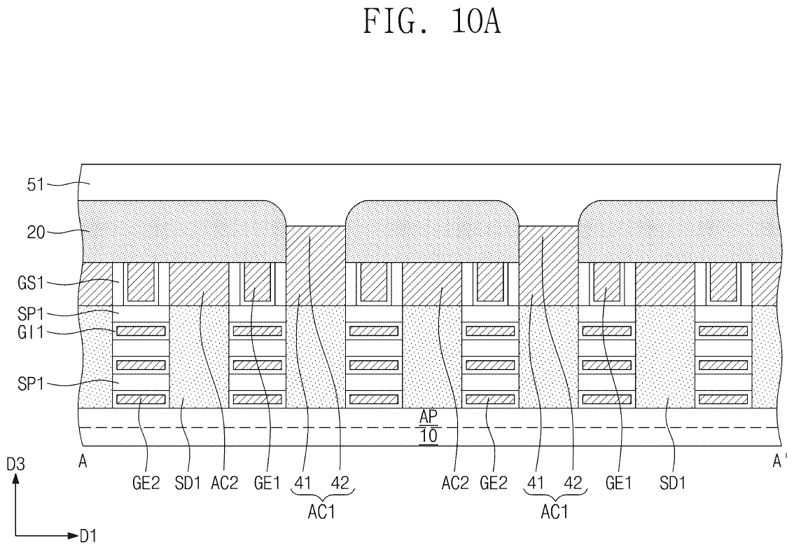

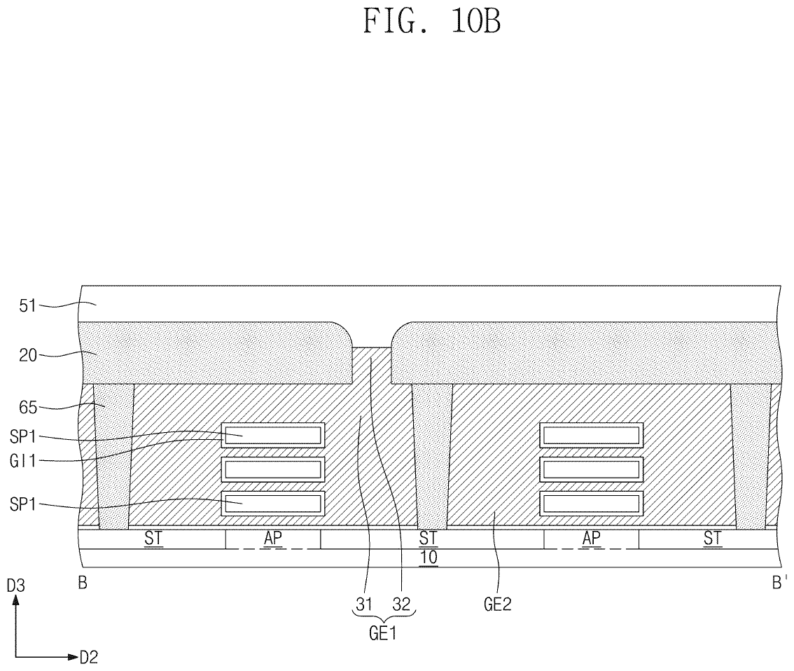

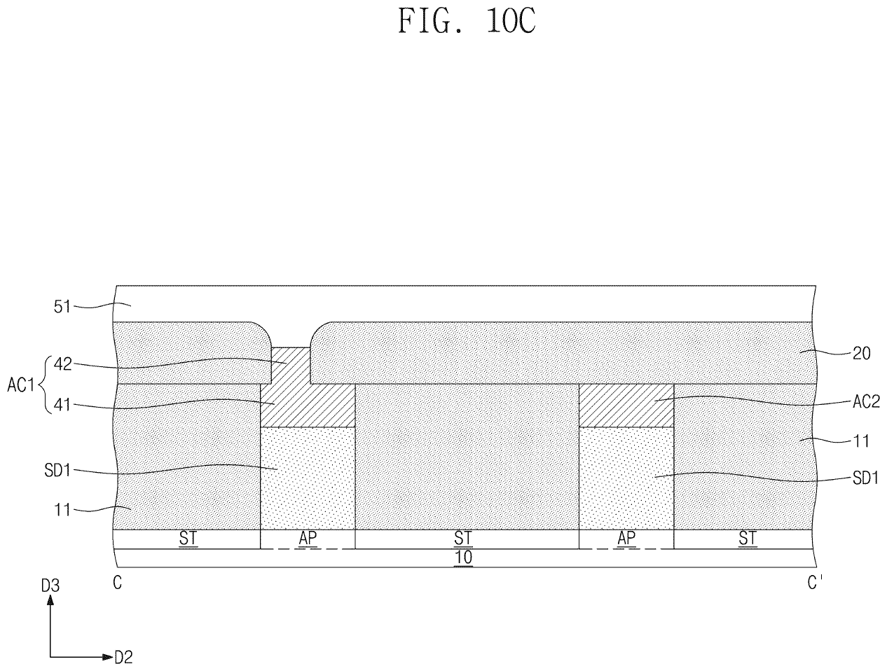

Referring to FIGS. 10A, 10B, and 10C, an upper portion of the preliminary interlayer insulating layer p51 may be removed. For example, the upper portion of the preliminary interlayer insulating layer p51 may be removed by a chemical mechanical polishing (CMP) process. The preliminary interlayer insulating layer p51 of which the upper portion is removed may be defined as the first interlayer insulating layer 51.

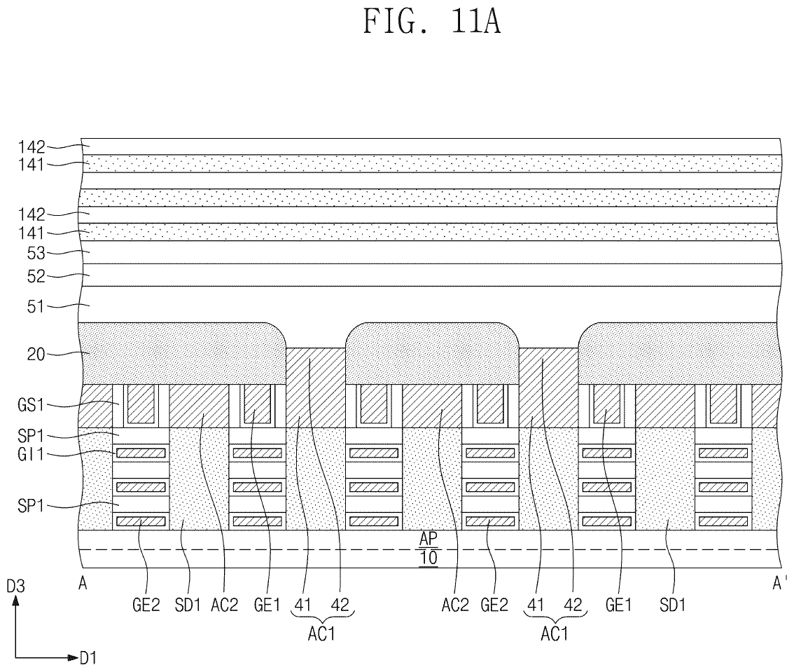

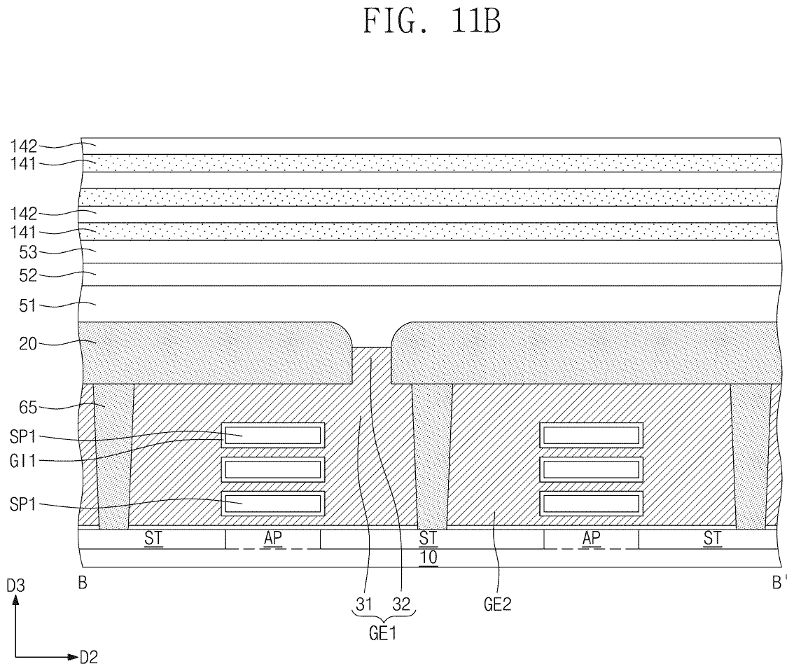

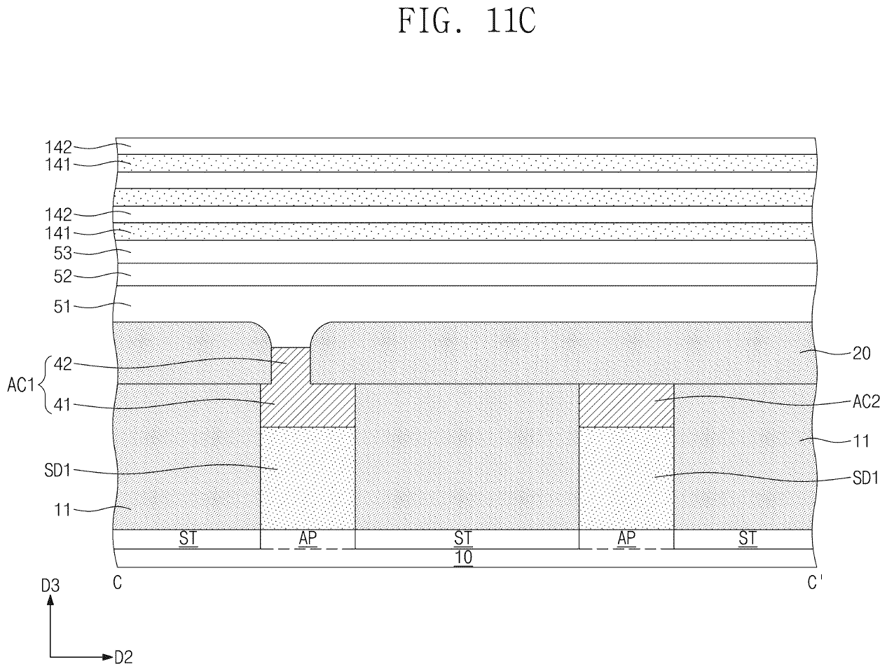

Referring to FIGS. 11A, 11B and 11C, a second interlayer insulating layer 52, a semiconductor layer 53, preliminary upper sacrificial layers 141 and preliminary upper semiconductor layers 142 may be formed.

According to some example embodiments, forming the second interlayer insulating layer 52, the semiconductor layer 53, the preliminary upper sacrificial layers 141 and the preliminary upper semiconductor layers 142 may include forming the semiconductor layer 53 on the second interlayer insulating layer 52, forming the preliminary upper sacrificial layers 141 and the preliminary upper semiconductor layers 142 on the semiconductor layer 53, and bonding the second interlayer insulating layer 52 to the first interlayer insulating layer 51. The second interlayer insulating layer 52 may be bonded to the first interlayer insulating layer 51 through, for example, a wafer bonding process.

The preliminary upper sacrificial layers 141 may include a material having etching selectivity for the preliminary upper semiconductor layers 142. For example, the preliminary upper sacrificial layers 141 may include silicon-germanium, and the preliminary upper semiconductor layers 142 may include silicon.

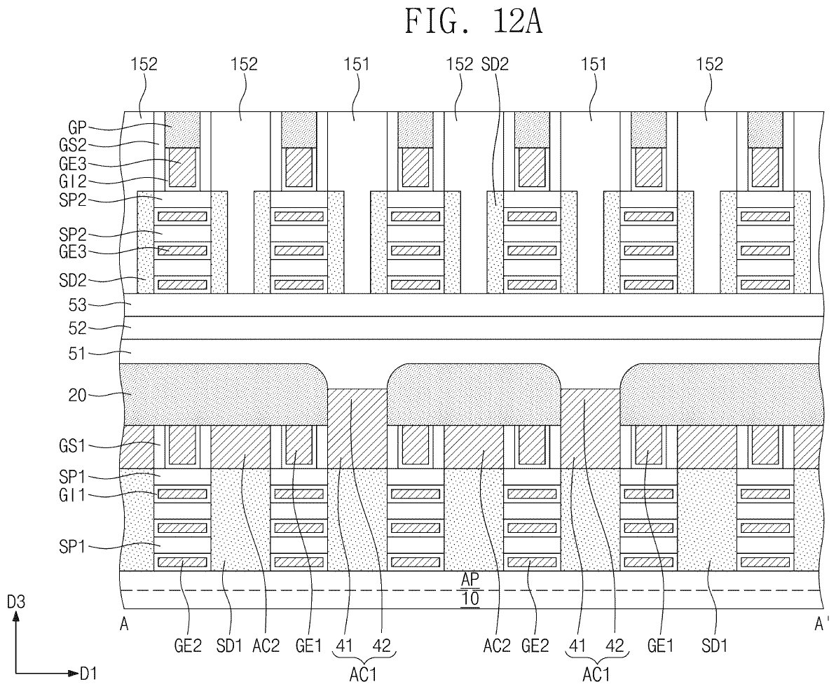

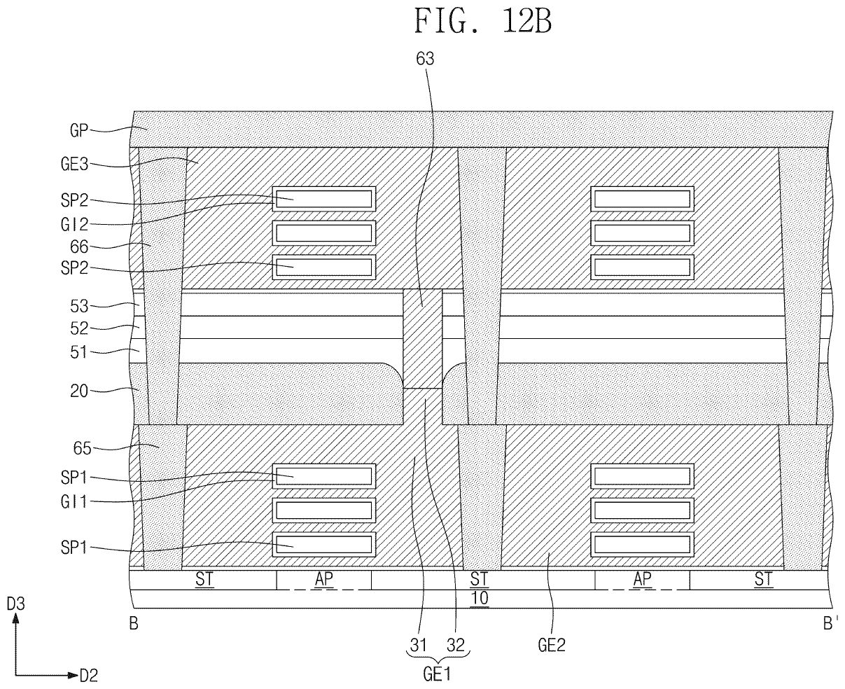

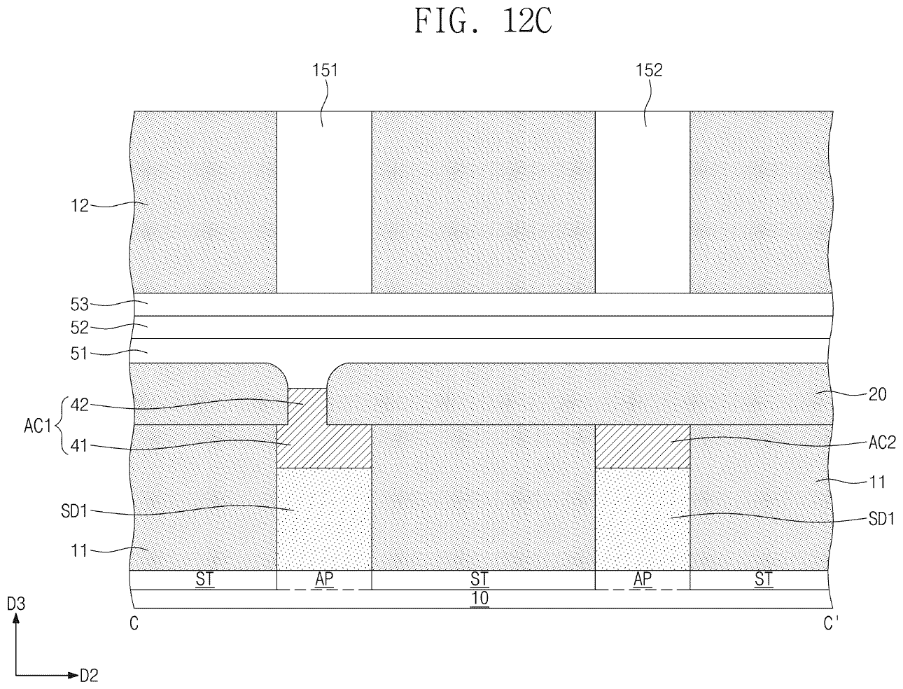

Referring to FIGS. 12A, 12B and 12C, upper semiconductor patterns SP2, upper source/drain patterns SD2, upper gate electrodes GE3, upper gate insulating layers GI2, upper gate spacers GS2 and gate capping patterns GP may be formed. The upper semiconductor patterns SP2, the upper source/drain patterns SD2, the upper gate electrodes GE3, the upper gate insulating layers GI2 and the upper gate spacers GS2 may be formed in a method similar to the method for forming the lower semiconductor patterns SP1, the lower source/drain patterns SD1, the preliminary gate electrodes pGE, the lower gate insulating layers GI1 and the lower gate spacers GS1.

A gate connection contact 63 may be formed. According to some example embodiments, the gate connection contact 63 may be formed after forming the upper gate insulating layer GI2 and before forming the upper gate electrode GE3.

The gate capping pattern GP may be formed on the upper gate electrode GE3. The gate capping pattern GP may include an insulating material.

Upper gate separation layers 66 may be formed. The upper gate electrode GE3 may be separated into a plurality of upper gate electrodes GE3 by the upper gate separation layers 66.

Upper filling insulating layers 12, first sacrificial insulating patterns 151 and second sacrificial insulating patterns 152 may be formed. According to some example embodiments, forming the upper filling insulating layers 12, the first sacrificial insulating patterns 151 and the second sacrificial insulating patterns 152 may include forming a preliminary upper filling insulating layer between the upper gate electrodes GE3, separating the preliminary upper filling insulating layer into the upper filling insulating layers 12, and forming the first and second sacrificial insulating patterns 151 and 152 between the upper filling insulating layers 12.

Each of the first and second sacrificial insulating patterns 151 and 152 may be provided between the upper source/drain patterns SD2. The first and second sacrificial insulating patterns 151 and 152 may be provided on the semiconductor layer 53. The first and second sacrificial insulating patterns 151 and 152 may include an insulating material. For example, the first and second sacrificial insulating patterns 151 and 152 may include oxide.

The first sacrificial insulating pattern 151 may overlap the first lower active contact AC1 in the third direction D3. The second sacrificial insulating pattern 152 may overlap the second lower active contact AC2 in the third direction D3.

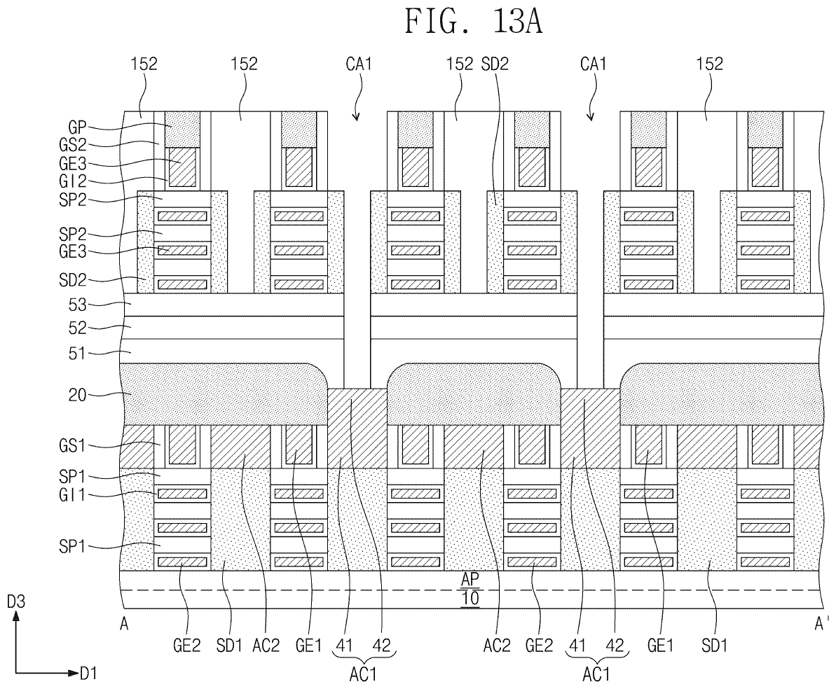

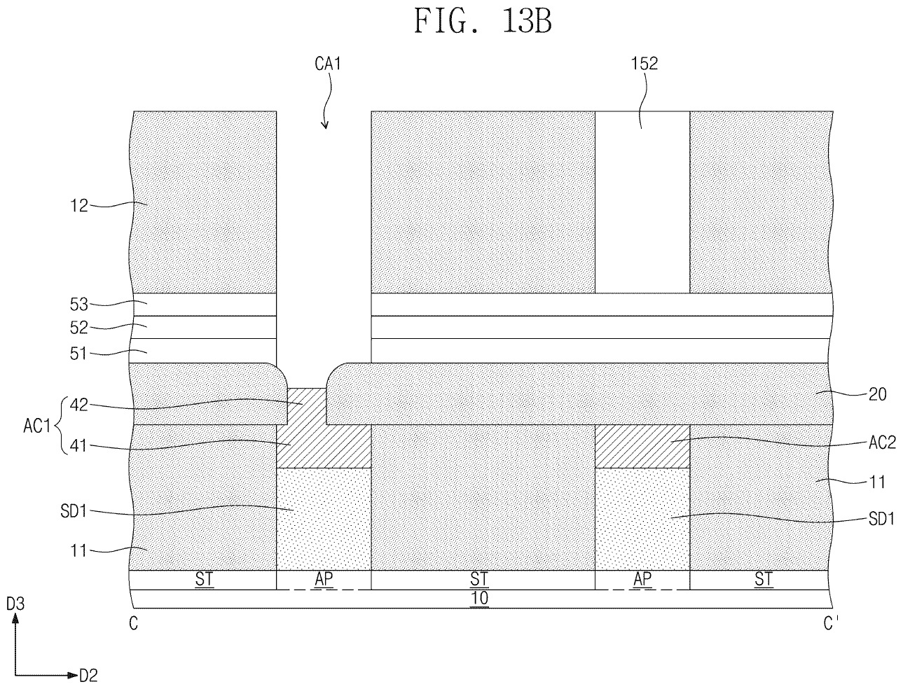

Referring to FIGS. 13A and 13B, the first sacrificial insulating patterns 151 may be removed. The first sacrificial insulating patterns 151 may be removed to form first cavities CA1. The semiconductor layer 53, the second interlayer insulating layer 52 and the first interlayer insulating layer 51 may be etched through the first cavities CA1. The semiconductor layer 53, the second interlayer insulating layer 52 and the first interlayer insulating layer 51 may be etched to expand the first cavity CA1. The active via portions 42 may be exposed through the first cavities CA1.

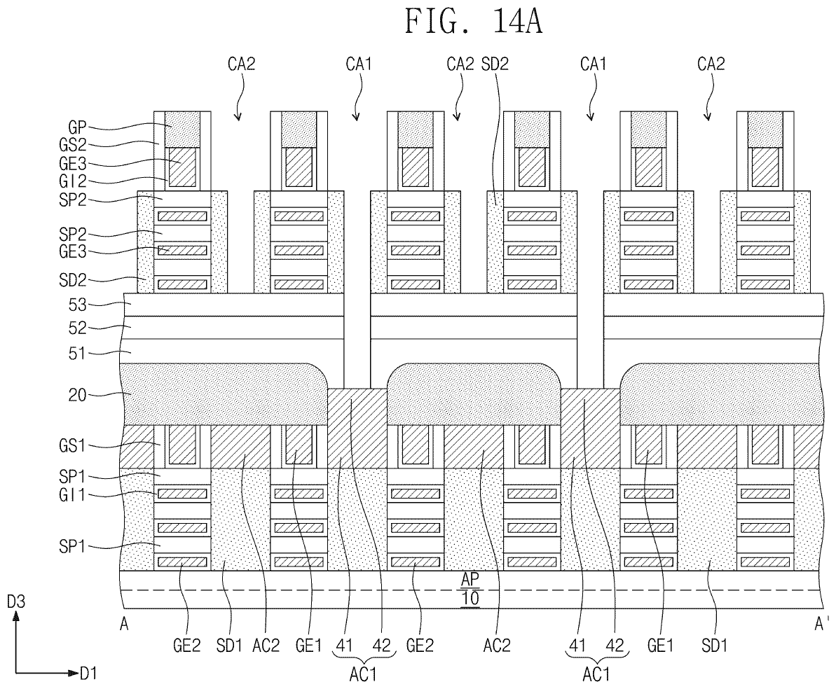

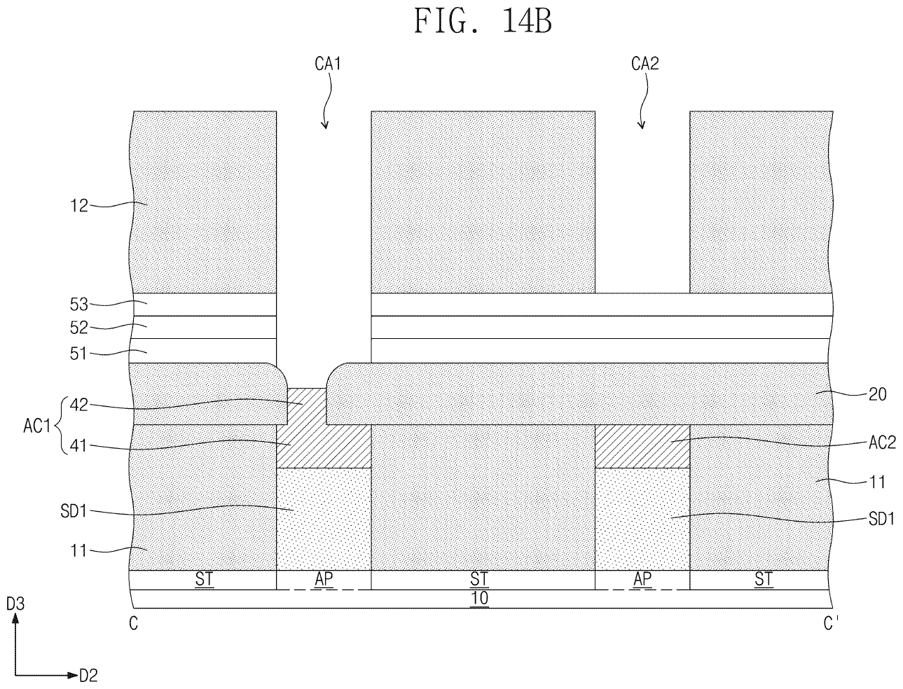

Referring to FIGS. 14A and 14B, the second sacrificial insulating patterns 152 may be removed. The second sacrificial insulating patterns 152 may be removed to form second cavities CA2.

According to some example embodiments, the first cavities CA1 and the second cavities CA2 may be simultaneously formed.

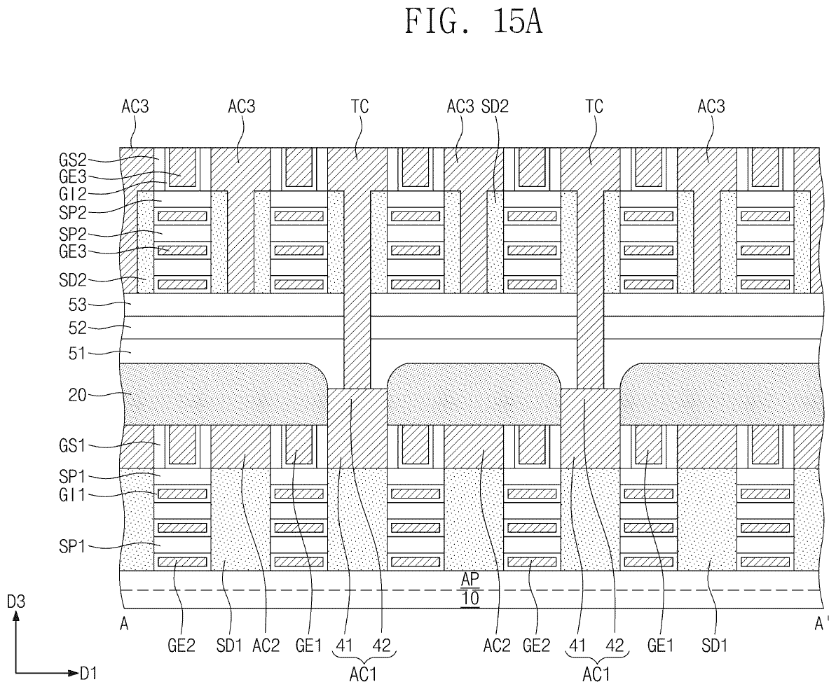

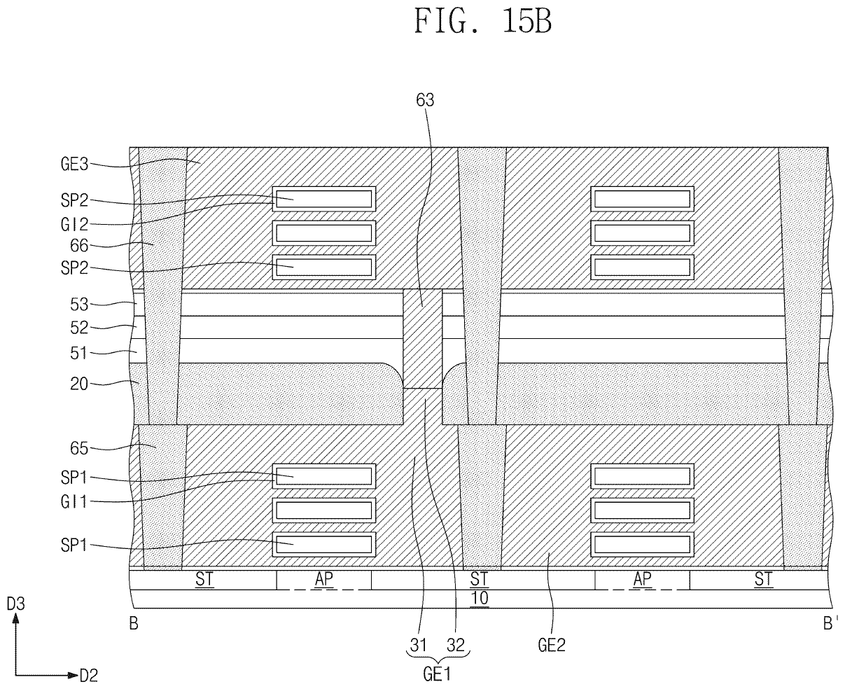

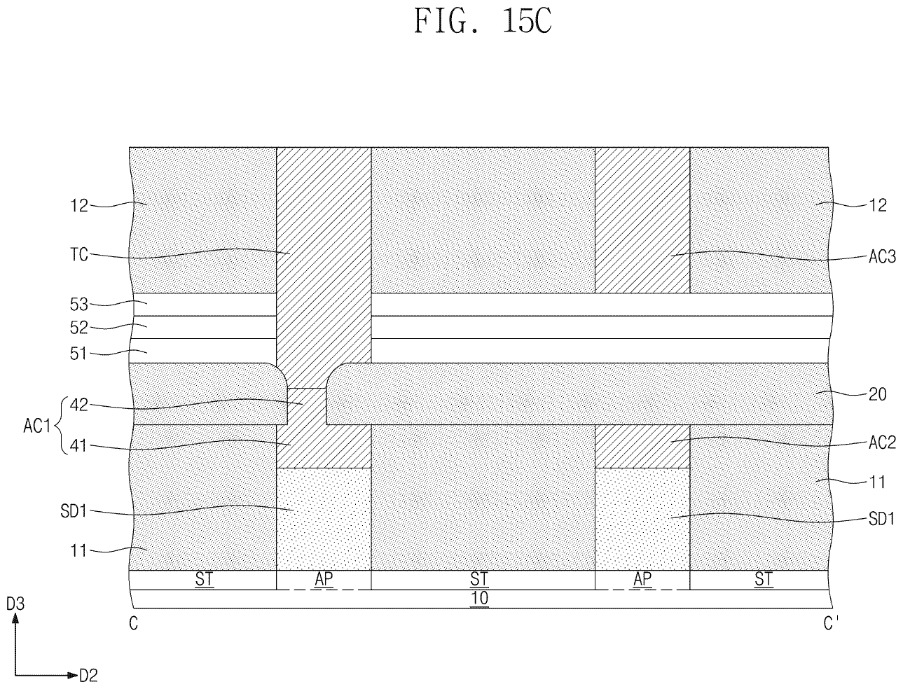

Referring to FIGS. 15A, 15B, and 15C, through active contacts TC and upper active contacts AC3 may be formed.

Forming the through active contacts TC and the upper active contacts AC3 may include forming a preliminary conductive layer that fills the first cavities CA1 and the second cavities CA2, and removing an upper portion of the preliminary conductive layer. The upper portion of the preliminary conductive layer may be removed so that the preliminary conductive layer may be separated into the through active contacts TC and the upper active contacts AC3. The gate capping pattern GP may be removed together with the upper portion of the preliminary conductive layer.

The through active contact TC may be formed in the first cavity CA1. The upper active contact AC3 may be formed in the second cavity CA2.

Referring to FIGS. 1A, 1B, 1C, and 1D, an upper insulating layer 61 may be formed. A contact 62 penetrating the upper insulating layer 61 may be formed.

Because in the method for manufacturing a semiconductor device according to some example embodiments, the gate via portion 32 and the active via portion 42 are formed, cost and time of a manufacturing process may be saved.

Because in the method for manufacturing a semiconductor device according to some example embodiments, the gate via portion 32 and the active via portion 42 are formed relatively far from each other, margin of the manufacturing process may be improved.

Because in the method for manufacturing a semiconductor device according to some example embodiments, the gate via portion 32 and the active via portion 42 are formed to have relatively small widths, margin of the manufacturing process may be improved.

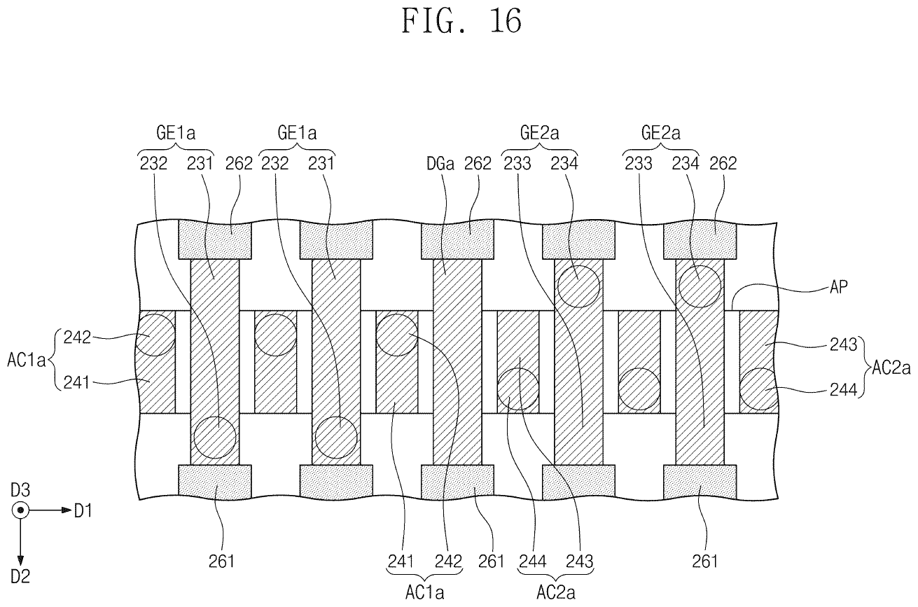

FIG. 16 is a plan view of a semiconductor device according to some example embodiments. The semiconductor device according to FIG. 16 may be similar to a semiconductor device according to FIGS. 1A to 1H except for what is illustrated below.

Referring to FIG. 16, the semiconductor device may include first lower gate electrodes GE1a and second lower gate electrodes GE2a overlapping the active pattern AP in the third direction D3.

First lower gate separation layers 261 and second lower gate separation layers 262 may be provided. The first lower gate separation layer 261 may be provided on a first side of the active pattern AP, and the second lower gate separation layer 262 may be provided on a second side opposed to the first side.

The first lower gate separation layers 261 may be arranged in the first direction D1. The second lower gate separation layers 262 may be arranged in the first direction D1. Each of the first lower gate electrode GE1a and the second lower gate electrode GE2a may be disposed between the first lower gate separation layer 261 and the second lower gate separation layer 262.

First lower active contacts AC1a and second lower active contacts AC2a may be provided. The first lower gate electrodes GE1a may be disposed between the first lower active contacts AC1a. The second lower gate electrodes GE2a may be disposed between the second lower active contacts AC2a. A dummy gate electrode DGa may be provided between the first lower active contacts AC1a and the second lower active contacts AC2a.

The first lower gate electrode GE1a may include a first gate conductive portion 231 and a first gate via portion 232. The second lower gate electrode GE2a may include a second gate conductive portion 233 and a second gate via portion 234.

The first lower active contact AC1a may include a first active conductive portion 241 and a first active via portion 242. The second lower active contact AC2a may include a second active conductive portion 243 and a second active via portion 244.

Each of the first gate via portion 232 and the second active via portion 244 may be disposed adjacent to the first lower gate separation layer 261. A distance between the first gate via portion 232 and the first lower gate separation layer 261 may be smaller than a distance between the first gate via portion 232 and the second lower gate separation layer 262. A distance between the second active via portion 244 and the first lower gate separation layer 261 may be smaller than a distance between the second active via portion 244 and the second lower gate separation layer 262.

Each of the second gate via portion 234 and the first active via portion 242 may be disposed adjacent to the second lower gate separation layer 262. A distance between the second gate via portion 234 and the second lower gate separation layer 262 may be smaller than a distance between the second gate via portion 234 and the first lower gate separation layer 261. A distance between the first active via portion 242 and the second lower gate separation layer 262 may be smaller than a distance between the first active via portion 242 and the first lower gate separation layer 261.

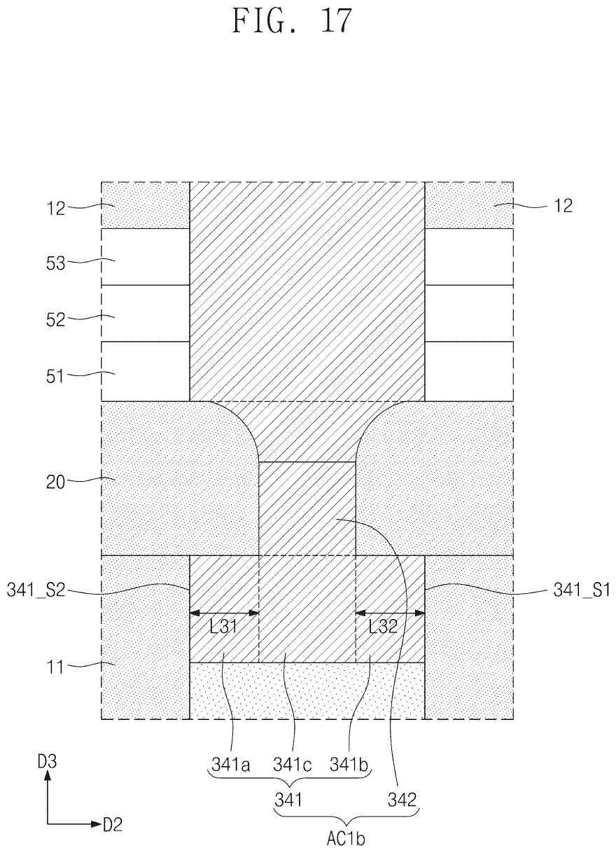

FIG. 17 is an enlarged cross-sectional view of a semiconductor device according to some example embodiments. The semiconductor device according to FIG. 17 may be similar to a semiconductor device according to FIGS. 1A to 1H except for what is illustrated below.

Referring to FIG. 17, a first lower active contact AC1b may include an active conductive portion 341 and an active via portion 342.

The active conductive portion 341 may include a first part 341a, a second part 341b and a third part 341c. A width in the second direction D2 of the first part 341a of the active conductive portion 341 may be the same as a width in the second direction D2 of the second part 341b of the active conductive portion 341.

The active conductive portion 341 may include a first sidewall 341_S1 and a second sidewall 341_S2. A distance L31 in the second direction D2 between the second sidewall 341_S2 of the active conductive portion 341 and the third part 341c of the active conductive portion 341 may be the same as a distance L32 in the second direction D2 between the first sidewall 341_S1 of the active conductive portion 341 and the third part 341c of the active conductive portion 341.

The distance L31 in the second direction D2 between the second sidewall 341_S2 of the active conductive portion 341 and the active via portion 342 may be the same as the distance L32 in the second direction D2 between the first sidewall 341_S1 of the active conductive portion 341 and the active via portion 342.

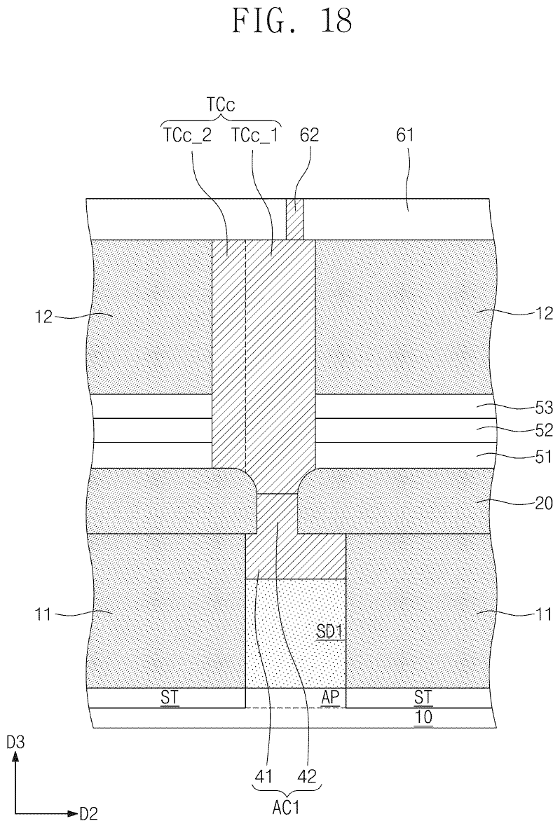

FIG. 18 is an enlarged cross-sectional view of a semiconductor device according to some example embodiments. The semiconductor device according to FIG. 18 may be similar to a semiconductor device according to FIGS. 1A to 1H except for what is illustrated below.

Referring to FIG. 18, a through active contact TCc may include a first part TCc_1 overlapping the first lower active contact AC1 in the third direction D3 and a second part TCc_2 not overlapping the first lower active contact AC1 in the third direction D3.

According to some example embodiments, misalign may occur in a process of forming the through active contact TCc to form the second part TCc_2 of the through active contact TCc.

Although in the semiconductor device according to some example embodiments, misalign occurs in the process of forming the through active contact TCc, a sufficient contact area between the through active contact TCc and the active via portion 42 may be secured.

Because semiconductor devices according to some example embodiments of the inventive concepts include an active via portion and a gate via portion, a short circuit between an active contact and a gate electrode may be reduced or prevented.

Although some example embodiments of the present inventive concepts have been described, it is understood that the present inventive concepts should not be limited to these example embodiments but various changes and modifications can be made by one ordinary skilled in the art within the spirit and scope of the present inventive concepts as hereinafter claimed.

What is claimed is:

1. A semiconductor device comprising:
a lower source/drain pattern;
a lower channel structure connected to the lower source/drain pattern;
a lower gate electrode overlapping the lower channel structure, the lower gate electrode extending in a first direction;
a lower active contact on the lower source/drain pattern;
an upper channel structure overlapping the lower channel structure;
an upper source/drain pattern connected to the upper channel structure;
an upper gate electrode overlapping the upper channel structure, the upper gate electrode extending in the first direction;
an interlayer structure between the lower channel structure and the upper channel structure; and
a through active contact extending through the interlayer structure, the through active contact electrically connected to the upper source/drain pattern and the lower active contact,
wherein the lower active contact includes an active conductive portion and an active via portion, the active conductive portion being on the lower source/drain pattern, the active via portion being on the active conductive portion, and
a width in the first direction of the active conductive portion is greater than a width in the first direction of the active via portion.

2. The semiconductor device of claim 1, wherein an upper surface of the active via portion is in contact with a lower surface of the through active contact.

3. The semiconductor device of claim 1, wherein
the through active contact comprises a lower portion in contact with the active via portion and an upper portion in contact with the upper source/drain pattern, and
a sidewall of the lower portion of the through active contact is curved.

4. The semiconductor device of claim 3, further comprising:
a mask layer in contact with an upper surface of the active conductive portion, a sidewall of the active via portion, and the sidewall of the lower portion of the through active contact,
wherein the mask layer includes a curved surface in contact with the sidewall of the lower portion of the through active contact.

5. The semiconductor device of claim 1, wherein
the lower gate electrode comprises a gate conductive portion and a gate via portion, the gate conductive portion overlapping the lower channel structure, the gate via portion being on the gate conductive portion, and
a width in the first direction of the gate conductive portion is greater than a width in the first direction of the gate via portion.

6. The semiconductor device of claim 5, further comprising:
a gate connection contact in contact with the gate via portion and the upper gate electrode,
wherein the gate connection contact penetrates the interlayer structure.

7. The semiconductor device of claim 1, further comprising:
a mask layer on the lower gate electrode,
wherein the interlayer structure includes
a first interlayer insulating layer on the mask layer, and
a second interlayer insulating layer on the first interlayer insulating layer, and both the first and second interlayer insulating layers include a first insulating material.

8. The semiconductor device of claim 7, wherein the mask layer comprises a second insulating material having etching selectivity with respect to the first insulating material.

9. A semiconductor device comprising:
a lower source/drain pattern;
a lower channel structure connected to the lower source/drain pattern;
a lower gate electrode overlapping the lower channel structure, the lower gate electrode extending in a first direction;
a lower active contact on the lower source/drain pattern;
an upper channel structure overlapping the lower channel structure;
an upper source/drain pattern connected to the upper channel structure;
an upper gate electrode overlapping the upper channel structure, the upper gate electrode extending in the first direction;
an interlayer structure between the lower channel structure and the upper channel structure;
a mask layer between the interlayer structure and the lower active contact; and
a through active contact extending through the interlayer structure, the through active contact electrically connected to the upper source/drain pattern and the lower active contact,
wherein the lower active contact includes an active conductive portion and an active via portion, the active conductive portion being on the lower source/drain pattern, the active via portion being on the active conductive portion, and
the mask layer is in contact with an upper surface of the active conductive portion and a sidewall of the active via portion.

10. The semiconductor device of claim 9, wherein an upper surface of the active via portion has a lower level than an upper surface of the mask layer.

11. The semiconductor device of claim 9, wherein
the mask layer comprises a curved surface surrounding a lower portion of the through active contact, and
the interlayer structure comprises an interposed portion between a lower portion of the through active contact and the curved surface.

12. The semiconductor device of claim 9, wherein a lower surface of the through active contact is in contact with an upper surface of the active via portion.

13. The semiconductor device of claim 9, wherein the active conductive portion comprises:
a first part;
a second part spaced apart from the first part in the first direction; and
a third part between the first part and the second part,
the third part of the active conductive portion overlaps the active via portion, and
a width in the first direction of the first part of the active conductive portion is smaller than a width in the first direction of the second part of the active conductive portion.

14. The semiconductor device of claim 13, wherein
the lower gate electrode comprises a gate conductive portion and a gate via portion, the gate conductive portion overlapping the lower channel structure, the gate via portion being on the gate conductive portion, and
a width in the first direction of the gate conductive portion is greater than a width in the first direction of the gate via portion.

15. The semiconductor device of claim 14, wherein a distance in the first direction between the gate via portion and the first part of the active conductive portion is greater than a distance in the first direction between the gate via portion and the second part of the active conductive portion.

16. The semiconductor device of claim 9, wherein the through active contact comprises a first part overlapping the lower active contact and a second part not overlapping the lower active contact.

17. The semiconductor device of claim 9, wherein the interlayer structure comprises:
a first interlayer insulating layer on the mask layer;
a second interlayer insulating layer on the first interlayer insulating layer; and
a semiconductor layer on the second interlayer insulating layer, and
the upper source/drain pattern is on the semiconductor layer.

18. A semiconductor device comprising:
a lower source/drain pattern;
a lower channel structure connected to the lower source/drain pattern;
a lower gate electrode overlapping the lower channel structure, the lower gate electrode extending in a first direction;
a lower active contact on the lower source/drain pattern;
an upper channel structure overlapping the lower channel structure;
an upper source/drain pattern connected to the upper channel structure;
an upper gate electrode overlapping the upper channel structure, the upper gate electrode extending in the first direction;
an interlayer structure between the lower channel structure and the upper channel structure;
a mask layer between the interlayer structure and the lower active contact;
a through active contact extending through the interlayer structure and the mask layer, the through active contact electrically connected to the upper source/drain pattern and the lower active contact; and
a gate connection contact electrically connected to the lower gate electrode and the upper gate electrode,
wherein the lower active contact includes an active conductive portion and an active via portion, the active conductive portion being on the lower source/drain pattern, the active via portion being on the active conductive portion,
the lower gate electrode includes a gate conductive portion and a gate via portion, the gate conductive portion overlapping the lower channel structure, the gate via portion being on the gate conductive portion, and
the active via portion and the gate via portion are at higher levels than a lower surface of the mask layer.

19. The semiconductor device of claim 18, wherein
a width in the first direction of the gate conductive portion is greater than a width in the first direction of the gate via portion, and
a width in the first direction of the active conductive portion is greater than a width in the first direction of the active via portion.

20. The semiconductor device of claim 18, wherein an upper surface of the gate via portion and an upper surface of the active via portion are at lower levels than an upper surface of the mask layer.
